(19) United States
(12) Patent Application Publication
(10) Pub. No.: US 2010/0091623 A1
(43) Pub. Date: Apr. 15, 2010

(54) FREQUENCY CHARACTERISTIC ADJUSTING CIRCUIT, RECEIVING INTERFACE CIRCUIT, AND MAGNETIC STORAGE DEVICE

(75) Inventor: Isao Tsuyama, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/560,992

(22) Filed: Sep. 16, 2009

(30) Foreign Application Priority Data
Oct. 10, 2008 (JP) 2008-263846

(51) Int. Cl. G11B 20/00; H04L 27/06; H03B 19/00

(52) U.S. Cl. 369/47.17; 375/344; 327/113; G9B/20

(57) ABSTRACT

According to one embodiment, a frequency characteristic adjusting circuit includes a cutoff range adjusting module and a control signal inputting module. The cutoff range adjusting module is connected to an AC coupling circuit capacitively coupled with a signal transmission path, and allows an output signal from the AC coupling circuit to pass through such that a low cutoff range in the frequency characteristic of the AC coupling circuit varies. The control signal inputting module receives a control signal to control a zero-point frequency based on a numerator polynomial of a transfer function of the cutoff range adjusting module and a pole frequency based on a denominator polynomial of the transfer function. The numerator polynomial is equalized to a denominator polynomial of a transfer function of the AC coupling circuit by the control signal. A cutoff frequency is determined by the pole frequency according to the control signal.

### CROSS-REFERENCE TO RELATED APPLICATIONS

This application is based upon and claims the benefit of priority from Japanese Patent Application No. 2008-263846, filed Oct. 10, 2008, the entire contents of which are incorporated herein by reference.

### BACKGROUND

1. Field

One embodiment of the invention relates to a frequency characteristic adjusting circuit that adjusts a frequency characteristic of an input signal, a receiving interface circuit comprising the frequency characteristic adjusting circuit, and a magnetic storage device.

2. Description of the Related Art

In a transmission path of signals between communication apparatuses and in information apparatuses, an alternate current (AC) coupling circuit for removing a direct current (DC) component of a signal has been widely used. For example, in a receiving end in a multiple branching transmission path where a ratio of input/output counts becomes 1:n (n: an integer 2 or more) or a high-speed transmission path where a signal frequency exceeds 1 GHz even though a ratio of input/output counts becomes 1:1, matching termination needs to be performed according to characteristic impedance of the transmission path.

FIG. 22 is a diagram of a configuration of a general AC coupling circuit. FIG. 22 illustrates a C-R differentiating circuit that is a primary high-pass filter as an example of a most general AC coupling circuit. The C-R differentiating circuit comprises a coupling capacitor C1 that is serially connected to a transmission path and a terminating resistor R2 that is connected between the transmission path and a ground. In the C-R differentiating circuit, the terminating resistor R2 functions as a resistor to terminate the transmission path. In a circuit where matching termination in a receiving end is needed, for example, a distributed constant circuit where a high frequency signal is transmitted, generally, a resistance value of the terminating resistor R2 needs to be matched with characteristic impedance of a transmission path.

In this case, a transfer function of the C-R differentiating circuit and a step function indicating a step response thereof is represented are represented by Equations 1 and 2, respectively, as follows:

$$\begin{matrix}{T}_{HP} ( S ) = \frac{S}{S + ω z} & ( 1 ) \\ \begin{matrix}{f}_{HP} ( t ) = \frac{1}{2 π j} \cdot {\int }_{- j ∞}^{+ j ∞} \frac{1}{S} \cdot {T}_{HP} ( S ) \cdot {e}^{S \cdot t} \cdot d S \\ = exp ( - ω z \cdot t )\end{matrix} & ( 2 )\end{matrix}$$

where S is a Laplace operator and ωz is a low-frequency cutoff in the C-R differentiating circuit.

FIG. 23 is a diagram for explaining an aspect of a step response in an AC coupling circuit. The C-R differentiating circuit has a time constant τ according to a capacity of a coupling capacitor C1 and a resistance value of a terminating resistor R2, that is, a capacity Cp and a resistance value Rz, and the low-frequency cutoff ωz is determined by these values. As illustrated in FIG. 23, if a rectangular-wave signal is input to the C-R differentiating circuit, sag according to the low-frequency cutoff ωz is generated in an output waveform thereof, that is, a step response waveform. Accordingly, in the AC coupling circuit, a value of the capacity Cp is selected such that the amount of sag is greatly reduced while a required pass-band characteristic is realized. In the case of a lumped-constant circuit where a low frequency signal is transmitted, a constant of the circuit may be set according to a frequency component of the transmitted signal, and a degree of freedom of a combination of the capacity Cp and the resistance value Rz is relatively high.

Meanwhile, with the recent development of information transmission technologies, it has been increasingly needed to process a plurality of different speeds of signals in one apparatus. For example, in a magnetic disk device, such as hard disk drive (HDD), a zone-bit recording method that varies a signal transmission speed according to a read/write area to make a recording density from the inner circumferential side of a recording medium to the outer circumferential side thereof uniform may be used. In this scheme, a frequency parameter of a read channel is adjusted for every read area. At this time, a low-frequency cutoff of an AC coupling module that is provided in a transmission path of a read signal is also appropriately switched. As a switching method, a method that discretely switches a terminating resistance value is generally used.

As a technology related to the above, a circuit that controls a frequency characteristic of a gm-C filter circuit comprises a buffer amplifier and a filter circuit having a transconductance amplifier, and a driving current of an operational transconductance amplifier (OTA) of each of the filter circuit, the buffer amplifier, and the gm-C filter circuit is constantly controlled on the basis of an output of the circuit (see, for example, Japanese Patent Application Publication (KOKAI) No. 2004-312544). Further, in a filter circuit that comprises a resistor and a capacitor, a variable voltage source and a transistor to vary a current flowing through the resistor are provided, and a cutoff frequency of the filter circuit is controlled (see, for example, Japanese Patent Application Publication (KOKAI) No. 2000-244281).

As described above, with respect to the AC coupling circuit using the C-R differentiating circuit, it is required to vary a low-frequency cutoff. To vary the low-frequency cutoff, either the capacity Cp or the resistance value Rz may be adjusted or both the capacity and the resistance value may be adjusted. However, since the capacitor and the resistor are basically passive elements, it is easy to discretely vary these values, but it is difficult to continuously vary the values.

Further, in the circuit where matching termination is needed, the resistance value Rz needs to be matched with the characteristic impedance of the transmission path. For this reason, if the resistance value Rz is varied to control the low-frequency cutoff, this causes mismatching of the impedance in the transmission path, which may result in generating a distortion due to reflection at the time of transmitting a high frequency signal.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary diagram of a frequency characteristic adjusting circuit according to a first embodiment of the invention;

FIG. 2 is an exemplary diagram of a configuration of a signal transmission system where the frequency characteristic adjusting circuit is applied;

FIG. 3 is an exemplary diagram of the outline of a circuit example 2-1 of the frequency characteristic adjusting circuit;

FIG. 4 is an exemplary diagram of a frequency characteristic of each module in the circuit example 2-1;

FIG. 5 is an exemplary block diagram where a transfer function of the circuit example 2-1 is expanded;

FIG. 6 is an exemplary diagram of the outline of a circuit example 2-2 of the frequency characteristic adjusting circuit;

FIG. 7 is an exemplary diagram of a frequency characteristic of each module in the circuit example 2-2;

FIG. 8 is an exemplary block diagram where a transfer function of the circuit example 2-2 is expanded;

FIG. 9 is an exemplary block diagram where a transfer function of a circuit example 2-3 is expanded;

FIG. 10 is an exemplary diagram of a configuration where the circuit example 2-1 of the frequency characteristic adjusting circuit is realized in a single end type;

FIG. 11 is an exemplary diagram of a configuration where the circuit example 2-1 of the frequency characteristic adjusting circuit is realized in a differential type;

FIG. 12 is an exemplary diagram of a configuration where the circuit example 2-2 of the frequency characteristic adjusting circuit is realized in a single end type;

FIG. 13 is an exemplary diagram of a configuration where the circuit example 2-2 of the frequency characteristic adjusting circuit is realized in a differential type;

FIG. 14 is an exemplary diagram of a configuration of a Gm circuit;

FIG. 15 is an exemplary block diagram where a transfer function of a frequency characteristic adjusting circuit according to a third embodiment of the invention is expanded;

FIG. 16 is an exemplary plan view of an inner configuration of an HDD according to a fourth embodiment of the invention;

FIG. 17 is an exemplary diagram of a circuit configuration of a reproduction signal system in the HDD;

FIG. 18 is an exemplary diagram of a configuration of a circuit example 4-1 of the frequency characteristic adjusting circuit;

FIG. 19 is an exemplary diagram of a configuration of a circuit example 4-2 of the frequency characteristic adjusting circuit;

FIG. 20 is an exemplary diagram of a configuration of a read channel comprising a noise suppressing function;

FIG. 21 is an exemplary diagram of a signal waveform in each module of the read channel of FIG. 20;

FIG. 22 is an exemplary diagram of a configuration of a general AC coupling circuit; and

FIG. 23 is an exemplary diagram for explaining an aspect of a step response in an AC coupling circuit.

### DETAILED DESCRIPTION

Various embodiments according to the invention will be described hereinafter with reference to the accompanying drawings. In general, according to one embodiment of the invention, a frequency characteristic adjusting circuit adjusts a frequency characteristic of an input signal, and comprises a cutoff range adjusting module and a control signal inputting module. The cutoff range adjusting module is configured to be connected to an alternate current coupling circuit capacitively coupled with a signal transmission path and matching terminated, and allow an output signal from the alternate current coupling circuit to pass through such that a low cutoff range in the frequency characteristic of the alternate current coupling circuit varies. The control signal inputting module is configured to receive a control signal to control a zero-point frequency based on the numerator polynomial of a transfer function of the cutoff range adjusting module and a pole frequency based on the denominator polynomial of the transfer function. The numerator polynomial of the transfer function of the cutoff range adjusting module is equalized to the denominator polynomial of a transfer function of the alternate current coupling circuit by the control signal. A cutoff frequency of the low cutoff range is determined by the pole frequency according to the control signal.

According to another embodiment of the invention, a receiving interface circuit receives a signal through a signal transmission path. The receiving interface circuit comprises an alternate current coupling circuit and a frequency characteristic adjusting circuit. The alternate current coupling circuit is configured to be capacitively coupled with the signal transmission path and matching terminated. The frequency characteristic adjusting circuit is configured to receive an output signal from the alternate current coupling circuit and adjust the frequency characteristic of the alternate current coupling circuit. The frequency characteristic adjusting circuit comprises a cutoff range adjusting module and a control signal inputting module. The cutoff range adjusting module is configured to allow the output signal from the alternate current coupling circuit to pass through such that a low cutoff range in the frequency characteristic of the alternate current coupling circuit varies. The control signal inputting module is configured to receive a control signal to control a zero-point frequency based on the numerator polynomial of a transfer function of the cutoff range adjusting module and a pole frequency based on the denominator polynomial of the transfer function. The numerator polynomial of the transfer function of the cutoff range adjusting module is equalized to the denominator polynomial of a transfer function of the alternate current coupling circuit by the control signal. A cutoff frequency of the low cutoff range is determined by the pole frequency according to the control signal.

According to still another embodiment of the invention, a magnetic storage device records and reproduces a signal using a magnetic disk medium, and comprises an alternate current coupling circuit and a frequency characteristic adjusting circuit. The alternate current coupling circuit is configured to be capacitively coupled with a signal transmission path, where a signal read from the magnetic disk medium is transmitted, and matching terminated. The frequency characteristic adjusting circuit is configured to receive an output signal from the alternate current coupling circuit and adjust the frequency characteristic of the alternate current coupling circuit. The frequency characteristic adjusting circuit comprises a cutoff range adjusting module and a control signal inputting module. The cutoff range adjusting module is configured to allow the output signal from the alternate current coupling circuit to pass through such that a low cutoff range in the frequency characteristic of the alternate current coupling circuit varies. The control signal inputting module is configured to receive a control signal to control a zero-point frequency based on the numerator polynomial of a transfer function of the cutoff range adjusting module and a pole frequency based on the denominator polynomial of the transfer function. The numerator polynomial of the transfer function of the cutoff range adjusting module is equalized to the denominator polynomial of a transfer function of the alternate current coupling circuit by the control signal. A cutoff frequency of the low cutoff range is determined by the pole frequency according to the control signal.

### First Embodiment

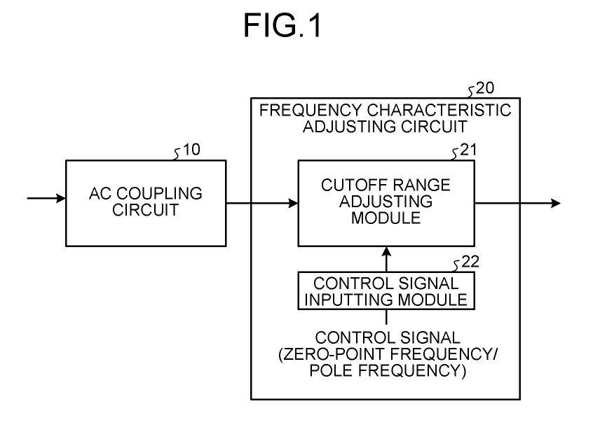

FIG. 1 is a diagram of a frequency characteristic adjusting circuit 20 according to a first embodiment of the invention. In FIG. 1, the frequency characteristic adjusting circuit 20 is connected to a rear stage of an AC coupling circuit 10 that is inserted into a transmission path of a signal. The AC coupling circuit 10 is capacitively coupled with the transmission path through a coupling capacitor and is matching terminated by a terminating resistor, and basically operates as a high-pass filter.

The frequency characteristic adjusting circuit 20 comprises a cutoff range adjusting module 21 and a control signal inputting module 22. The cutoff range adjusting module 21 has a frequency characteristic for shifting a low cutoff range in a frequency characteristic of the AC coupling circuit 10. The cutoff range adjusting module 21 basically has a frequency characteristic for offsetting at least a portion of the low-pass cutoff characteristic of the AC coupling circuit 10, and further shifts the low cutoff range of the AC coupling circuit 10 to the low-pass side.

The control signal inputting module 22 receives a control signal to continuously vary the frequency characteristic of the cutoff range adjusting module 21, and supplies the control signal to the cutoff range adjusting module 21. The control signal may be output from a predetermined circuit in the frequency characteristic adjusting circuit 20, and supplied from the outside of the frequency characteristic adjusting circuit 20. As will be described in detail below, as the control signal, a bias current may be used, which controls transconductance of a transconductance amplifier in the cutoff range adjusting module 21. Thereby, each frequency can be easily and continuously varied.

By the control signal, a zero-point frequency that is given by a numerator polynomial of a transfer function of the cutoff range adjusting module 21, and a pole frequency that is given by a denominator polynomial are arbitrarily set. Specifically, the zero-point frequency of the cutoff range adjusting module 21 is set as the same value as the low-frequency cutoff of the AC coupling circuit 10. The setting condition means that the numerator polynomial of the transfer function of the cutoff range adjusting module 21 matches the denominator polynomial of the transfer function of the AC coupling circuit 10. In a state where the setting condition is maintained, the pole frequency of the cutoff range adjusting module 21 varies. The pole frequency is set between a frequency “0” and the zero-point frequency in the setting condition.

As a result, the cutoff range adjusting module 21 operates to offset the low-pass cutoff characteristic of the AC coupling circuit 10, in a frequency range from the zero-point frequency to the pole frequency. Accordingly, in the frequency characteristics of the AC coupling circuit 10 and the cutoff range adjusting module 21, an approximately uniform pass characteristic is obtained in the frequency range from the zero-point frequency to the pole frequency. In addition, a new low-frequency cutoff in the frequency characteristics of the AC coupling circuit 10 and the cutoff range adjusting module 21 is set by the pole frequency of the cutoff range adjusting module 21. That is, a low cutoff range by the AC coupling circuit 10 further shifts to the low-pass side.

For example, when the transfer function of the frequency characteristic adjusting circuit 20 is set such that the pole frequency becomes “0”, in the frequency characteristics of the AC coupling circuit 10 and the cutoff range adjusting module 21, an approximately uniform pass characteristic is obtained in the entire frequency range of the zero-point frequency or less. Accordingly, the low cutoff range by the AC coupling circuit 10 can be cancelled.

If the frequency characteristic adjusting circuit 20 is provided at a rear stage of the AC coupling circuit 10, without varying a load in the AC coupling circuit 10, the low-frequency cutoff can vary or the pass characteristic thereof can be made uniform. Accordingly, even in a transmission path where a high-speed signal having a transmission speed of 1 GHz or more is transmitted, a frequency characteristic can be adjusted while matching in the transmission path is maintained.

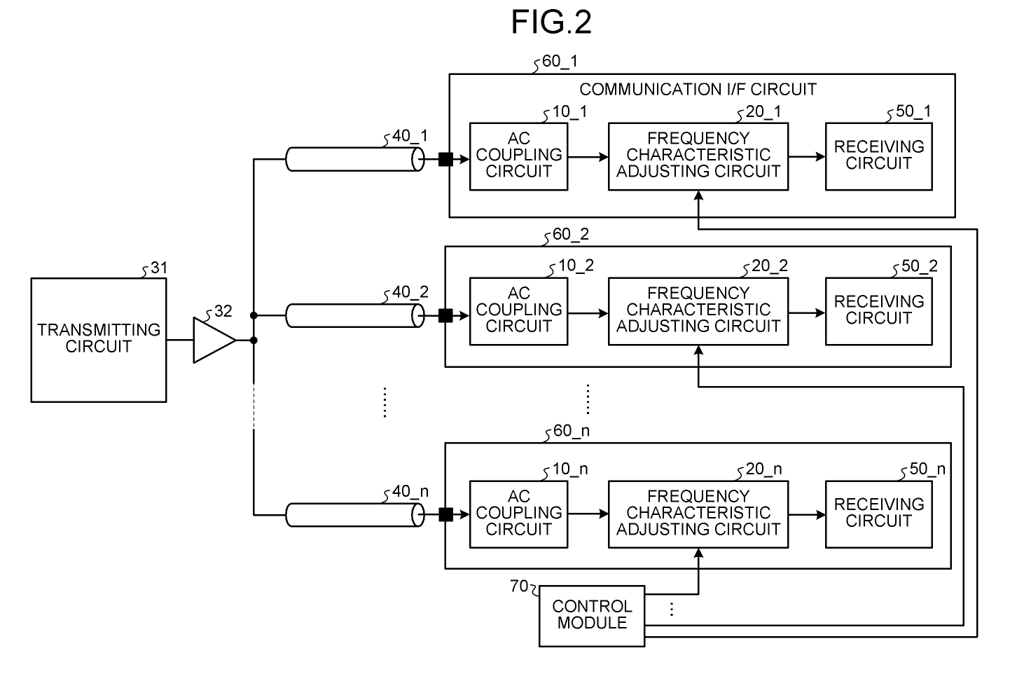

FIG. 2 is a diagram of a configuration of a signal transmission system where a frequency characteristic adjusting circuit is applied. The AC coupling circuit 10 and the frequency characteristic adjusting circuit 20 can be applied to a receiving end of a multiple branching transmission path where a ratio of input/output counts becomes 1:n (n: an integer 2 or more) as illustrated in FIG. 2, in addition to the transmission path where a ratio of input/output counts becomes 1:1.

In FIG. 2, a signal transmitted from a transmitting circuit 31 is transmitted to n transmission paths 40_1 to 40_{—}n through a driving circuit 32. Individual receiving ends of the transmission paths 40_1 to 40_{—}n are matching terminated by corresponding AC coupling circuits 10_1 to 10_{—}n in the AC coupling circuit 10 of FIG. 1. In addition, rear stages of the AC coupling circuits 10_1 to 10_{—}n are connected to corresponding frequency characteristic adjusting circuits 20_1 to 20_{—}n in the frequency characteristic adjusting circuit 20 of FIG. 1. The signals transmitted from the frequency characteristic adjusting circuits 20_1 to 20_{—}n are received by receiving circuits 50_1 to 50_{—}n, respectively.

In this case, in the AC coupling circuits 10_1 to 10_{—}n, at least circuit parameters according to characteristic impedances of the corresponding transmission paths 40_1 to 40_{—}n are individually set. Accordingly, in the cutoff range adjusting modules in the frequency characteristic adjusting circuits 20_1 to 20_{—}n, in accordance with the circuit parameters of the corresponding AC coupling circuits 10_1 to 10_{—}n, the zero-point frequencies and the pole frequencies are set to realize required frequency characteristics. Thereby, the required frequency characteristics can be realized without causing mismatching with the impedances in the transmission paths 40_1 to 40_{—}n. Further, the frequency characteristics can be set to suppress the generation amount of sag in the AC coupling circuits 10_1 to 10_{—}n. As in the example illustrated in FIG. 2, the AC coupling circuits 10_1 to 10_{—}n, the frequency characteristic adjusting circuits 20_1 to 20_{—}n, and the receiving circuits 50_1 to 50_{—}n may be provided in communication interface (I/F) circuits 60_1 to 60_{—}n provided for the individual transmission paths 40_1 to 40_{—}n. Further, the frequency characteristic adjusting circuits 20_1 to 20_{—}n may be formed on individual semiconductor chips, respectively. Alternatively, the individual circuits of the frequency characteristic circuits 20_1 to 20_{—}n and at least a portion of the corresponding AC coupling circuits 10_1 to 10_{—}n and receiving circuits 50_1 to 50_{—}n may be formed on the same semiconductor chip.

In FIG. 2, control signals to set frequency characteristics of the individual cutoff range adjusting modules in the frequency characteristic adjusting circuits 20_1 to 20_{—}n may be output from a control module 70. The control module 70 may be provided for each of the frequency characteristic adjusting circuits 20_1 to 20_{—}n. In this case, the individual control modules 70 may be provided in the corresponding communication I/F circuits 60_1 to 60_{—}n.

As will be described in detail below, when the frequency characteristics in the cutoff range adjusting modules of the frequency characteristic adjusting circuits 20_1 to 20_{—}n are controlled by an externally supplied control current, the control module 70 may receive a digital control signal from an external circuit or device such as a central processing unit (CPU), and supply a control current according to the digital control signal to each of the frequency characteristic adjusting circuits 20_1 to 20_{—}n.

Next, a specific configuration example or application example of the frequency characteristic adjusting circuit will be described in detail.

### Second Embodiment

In a second embodiment of the invention, the case where the C-R differentiating circuit serving as the primary high-pass filter illustrated in FIG. 22 is applied as the AC coupling circuit will be described. In the second embodiment, as the frequency characteristic adjusting circuits that are provided at the rear stage of the AC coupling circuit, the configurations of three kinds of the following circuit examples 2-1 to 2-3 are exemplified.

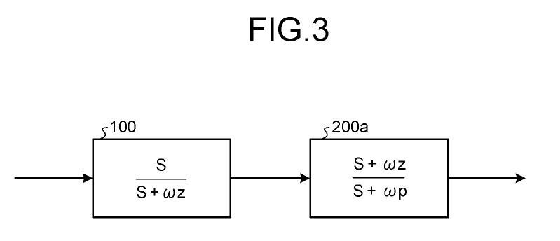

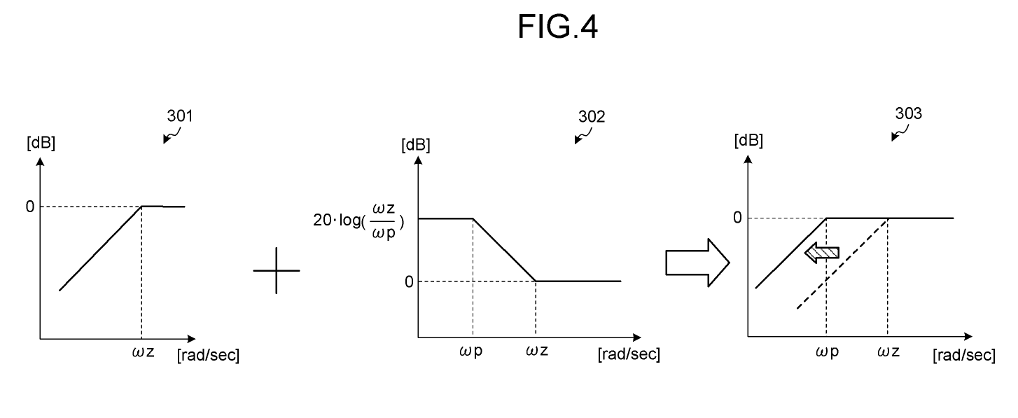

FIG. 3 is a diagram of the outline of a circuit example 2-1 of the frequency characteristic adjusting circuit. FIG. 4 is a diagram of a frequency characteristic of each module in the circuit example 2-1. In FIG. 3, an AC coupling circuit 100 is AC coupled to the transmission path by the C-R differentiating circuit and matching terminated. A graph 301 of FIG. 4 illustrates a frequency characteristic of the AC coupling circuit 100. As illustrated in the graph 301, the AC coupling circuit 100 operates a primary high-pass filter that blocks a signal component of not more than a low-frequency cutoff.

Meanwhile, a frequency characteristic adjusting circuit 200a is a bilinear circuit that has a bilinear transfer function where a denominator and a numerator are represented by a linear function. A transfer function of the frequency characteristic adjusting circuit 200a is represented by (S+ωz)/(S+ωp) (ωz>ωp≧0), as illustrated in FIG. 3. The frequency characteristic adjusting circuit 200a has a low-pass-emphasis-type frequency characteristic as illustrated in a graph 302 of FIG. 4. In addition, in a frequency characteristic curve thereof, two break frequencies comprising a zero-point frequency ωz given by a root of a denominator polynomial of a transfer function and a pole frequency ωp given by a root of a numerator polynomial exist.

In this case, as illustrated in the graphs 301 and 302 of FIG. 4, the zero-point frequency ωz of the frequency characteristic adjusting circuit 200a is set to the same value as the low-frequency cutoff of the AC coupling circuit 100. That is, as illustrated in FIG. 3, the transfer function of the AC coupling circuit 100 is represented as S/(S+ωz). In addition, the numerator polynomial of the transfer function of the frequency characteristic adjusting circuit 200a is set to match the denominator polynomial of the transfer function of the AC coupling circuit 100.

Thereby, the frequency characteristic adjusting circuit 200a operates to offset a cutoff characteristic of the AC coupling circuit 100, in a frequency domain ranging from the pole frequency ωp to the zero-point frequency ωz. A graph 303 of FIG. 4 illustrates frequency characteristics of the AC coupling circuit 100 and the frequency characteristic adjusting circuit 200a. As illustrated in the graph 303, in the frequency domain ranging from the pole frequency ωp to the zero-point frequency ωz, a pass characteristic is made to be almost uniform. In addition, the pole frequency ωp of the frequency characteristic adjusting circuit 200a becomes a new low-frequency cutoff of the entire circuit. Accordingly, if the pole frequency ωp varies, the low-frequency cutoff can be adjusted without changing the circuit parameter of the AC coupling circuit 100.

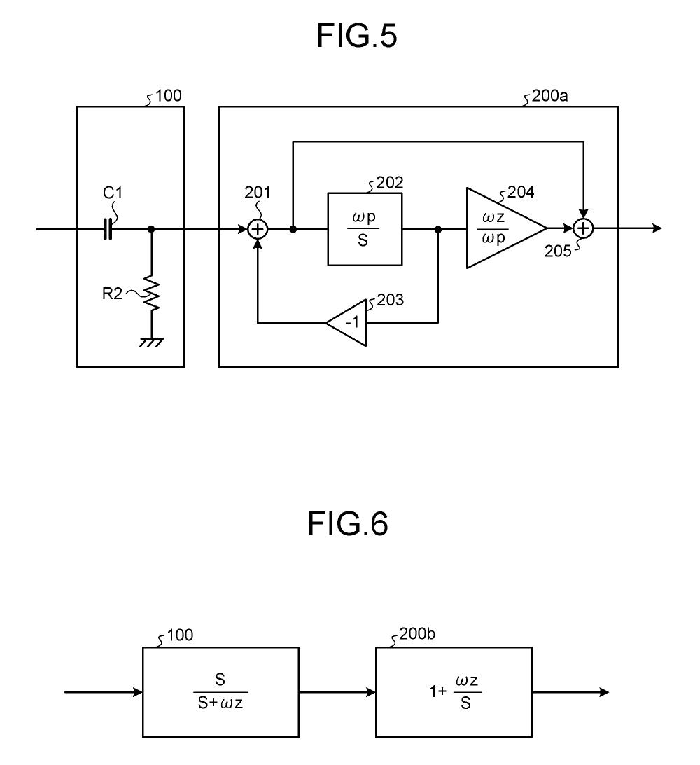

FIG. 5 is a block diagram where a transfer function of the circuit example 2-1 is expanded. As described above, the AC coupling circuit 100 comprises a coupling capacitor C1 that is serially connected to a transmission path and a terminating resistor R2 that is connected between the transmission path and a ground, and these circuit elements constitute a primary high-pass filter. Meanwhile, the frequency characteristic adjusting circuit 200a comprises an input-side adder 201, a perfect integrator 202, an inverter 203, an amplifier 204, and an output-side adder 205.

In one input terminal of the adder 201, an inverted signal obtained by inverting an output signal of the perfect integrator 202 by the inverter 203 is input. The adder 201 adds the inverted signal and an output signal from the AC coupling circuit 100, and outputs an added signal to the perfect integrator 202. The perfect integrator 202 is a circuit that is represented by a transfer function ωp/S, and has the pole frequency ωp as a cutoff frequency. The amplifier 204 amplifies the output signal from the perfect integrator 202 to (ωz/ωp) times as much. The adder 205 adds an output signal from the amplifier 204 and an output signal from the input-side adder 201. By this configuration, the bilinear transfer function is obtained.

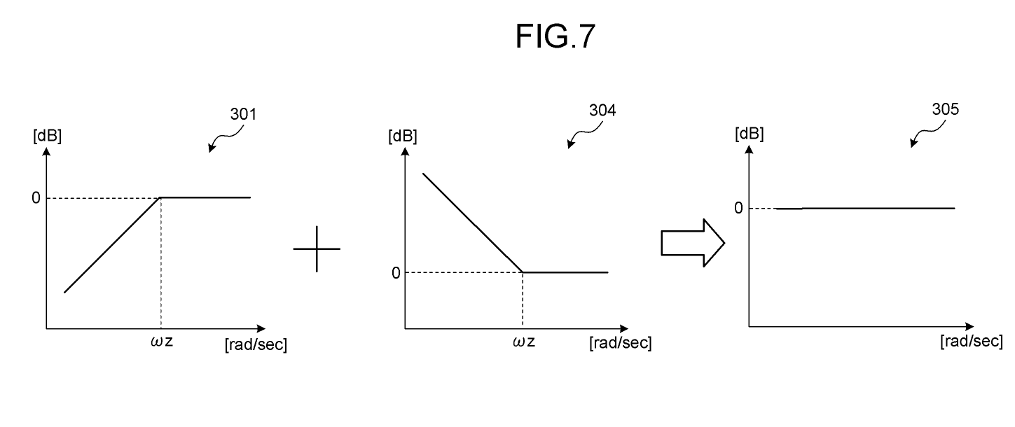

FIG. 6 is a diagram of the outline of the circuit example 2-2 of the frequency characteristic adjusting circuit. FIG. 7 is a diagram of a frequency characteristic of each module in the circuit example 2-2. In FIGS. 6 and 7, the constituent elements corresponding to those of FIGS. 3 and 4 are designated by the same reference numerals.

A frequency characteristic adjusting circuit 200b illustrated in FIG. 6 is an imperfect integration circuit that operates to offset a cutoff characteristic of the AC coupling circuit 100. In a frequency characteristic of the frequency characteristic adjusting circuit 200b, as illustrated in a graph 304 of FIG. 7, a low-pass characteristic becomes gradually high, when the zero-point frequency ωz is used as a boundary. A transfer function of the frequency characteristic adjusting circuit 200b is represented as 1+(ωz/S), as illustrated in FIG. 6.

In this case, as illustrated in the graphs 301 and 304 of FIG. 7, the zero-point frequency ωz of the frequency characteristic adjusting circuit 200b is set to the same value as the low-frequency cutoff of the AC coupling circuit 100. That is, a numerator polynomial of the transfer function of the frequency characteristic adjusting circuit 200b is set to match a denominator polynomial of a transfer function of the AC coupling circuit 100. Further, the transfer function of the frequency characteristic adjusting circuit 200b is equivalent to the case where the pole frequency ωp is set to “0”, in the transfer function of the frequency characteristic adjusting circuit 200a illustrated in FIG. 3.

As a result, the frequency characteristic adjusting circuit 200b operates to offset a pass characteristic of the AC coupling circuit 100, in a frequency domain of not more than the pole frequency ωp. A graph 305 of FIG. 7 illustrates frequency characteristics of the AC coupling circuit 100 and the frequency characteristic adjusting circuit 200b. As illustrated in the graph 305, a pass characteristic is made to be almost uniform in the entire frequency range. Accordingly, the low-frequency cutoff can be substantially removed without changing the circuit parameter of the AC coupling circuit 100. In addition, a signal can be suppressed from being deteriorated due to sag generation.

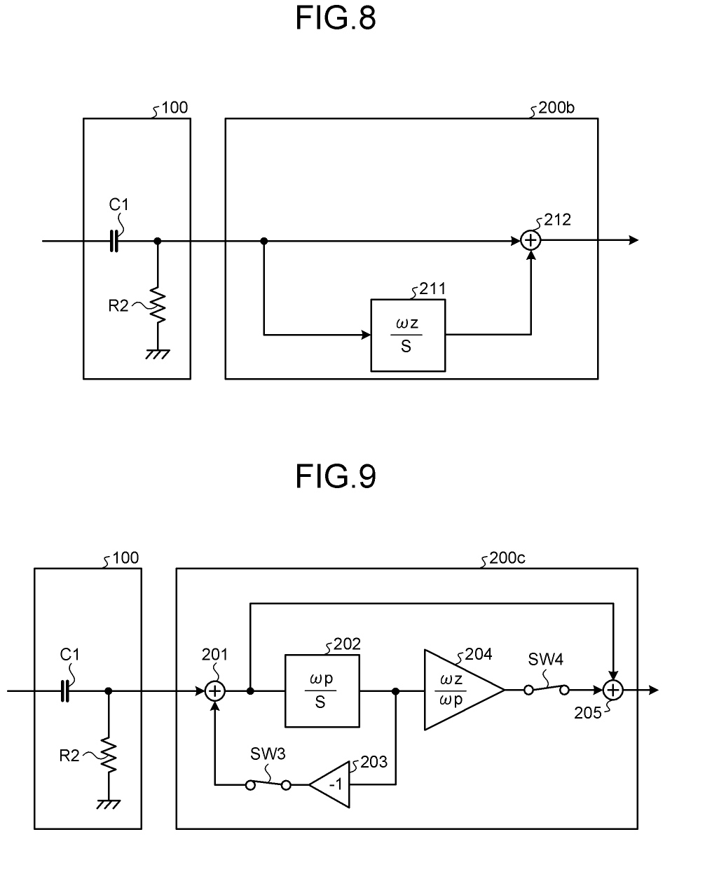

FIG. 8 is a block diagram where a transfer function of the circuit example 2-2 is expanded. In FIG. 8, the constituent elements corresponding to those of FIG. 5 are designated by the same reference numerals. The frequency characteristic adjusting circuit 200b comprises a perfect integrator 211 and an adder 212. An output signal from the AC coupling circuit 100 is split into the perfect integrator 211 and the adder 212. The perfect integrator 211 is a circuit that is represented by a transfer function ωz/S, and has the zero-point frequency ωz as a cutoff frequency. The adder 212 adds the output signal from the perfect integrator 211 and the output signal from the AC coupling circuit 100. With this configuration, the imperfect-integration-type transfer function is obtained.

FIG. 9 is a block diagram where a transfer function of a circuit example 2-3 is expanded. In FIG. 9, the constituent elements corresponding to those of FIG. 5 are designated by the same reference numerals. A frequency characteristic adjusting circuit 200c illustrated in FIG. 9 has the configuration in which switches SW3 and SW4 are added to the configuration of the frequency characteristic adjusting circuit 200a illustrated as the circuit example 2-1 in FIG. 5. The switch SW3 is inserted between the inverter 203 and the adder 201, and the switch SW4 is inserted between the amplifier 204 and the adder 205.

In the frequency characteristic adjusting circuit 200c, when both the switches SW3 and SW4 are turned on, i.e., enter in a closed state, the same circuit configuration as the case of the circuit example 2-1 is obtained. Accordingly, in this state, the frequency characteristic adjusting circuit 200c operates to shift or change the low-frequency cutoff by the pole frequency ωp. Further, when only the switch SW3 is turned off, i.e., enters in open state, a negative feedback loop from the perfect integrator 202 to the adder 201 is removed. In this state, the same frequency characteristic as the frequency characteristic adjusting circuit 200b illustrated as the circuit example 2-2 is realized.

As such, if the switch SW3 is turned on/off, the frequency characteristic according to an object can be obtained. For example, in the case of the multiple branching transmission path illustrated in FIG. 2, the frequency characteristic adjusting circuit 200c having the same configuration is disposed in a receiving end of each transmission path, and an ON/OFF operation of the switch SW3 is set for every transmission path. Thereby, it is possible to arbitrarily set whether or not to cutoff a signal component of not more than the pole frequency ωp, for every transmission path.

When both the switches SW3 and SW4 are turned off, an input signal is output as it is in the frequency characteristic adjusting circuit 200c, and the frequency characteristic by the AC coupling circuit 100 is maintained as it is. This state is used in a test mode.

Next, the configuration of the frequency characteristic adjusting circuit of the second embodiment will be specifically described. In this case, the frequency characteristic adjusting circuit comprises a transconductance amplifying circuit (hereinafter, “Gm circuit”) that operates as a voltage/current converting circuit and a capacitor.

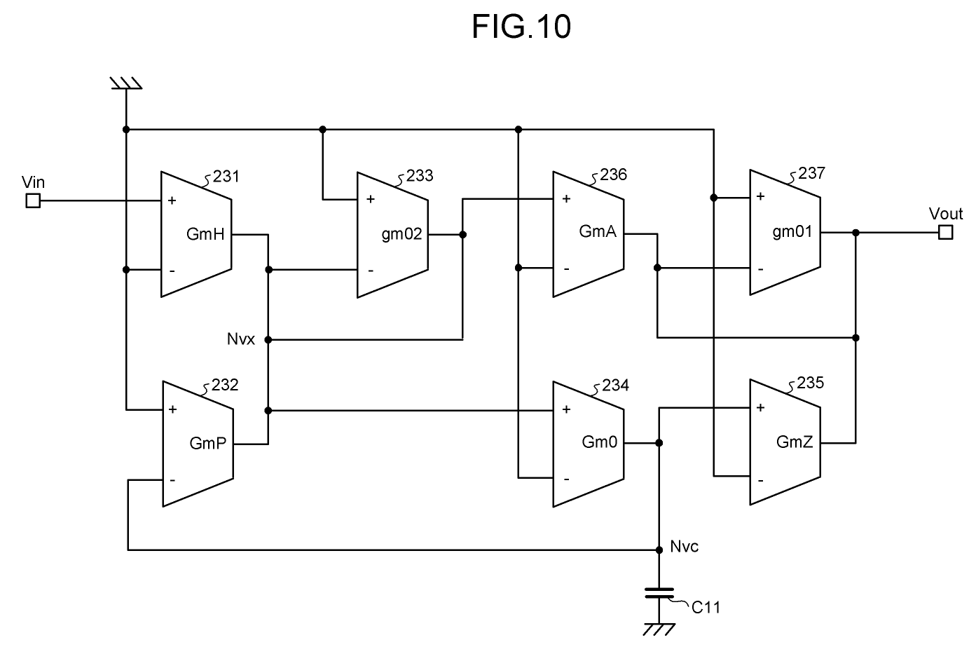

FIG. 10 is a diagram of a configuration where the circuit example 2-1 of the frequency characteristic adjusting circuit is realized in a single end type. The frequency characteristic adjusting circuit illustrated in FIG. 10 comprises Gm circuits 231 to 237 and a capacitor C11. In this case, the Gm circuits 231 to 237 have transconductances GmH, GmP, gm02, Gm0, GmZ, GmA, and gm01, respectively.

The output signal from the AC coupling circuit 100 is input to a normal-phase input terminal of the Gm circuit 231. An output signal from the Gm circuit 234 is input to a reverse-phase input terminal of the Gm circuit 232. Each output terminal of the Gm circuits 231 and 232 is commonly connected in a node Nvx, and the node Nvx is connected to a reverse-phase input terminal of the Gm circuit 233 and individual normal-phase input terminals of the Gm circuits 234 and 236. Further, an output signal from the Gm circuit 233 is negatively fed back to the reverse-phase input terminal thereof.

An output terminal of the Gm circuit 234 is connected to a normal-phase input terminal of the Gm circuit 235, a reverse-phase input terminal of the Gm circuit 232, and one terminal of the capacitor C11, in the node Nvc. The other terminal of the capacitor C11 is connected to a ground.

Output terminals of the Gm circuits 235 and 236 are connected to a reverse-phase input terminal of the Gm circuit 237. An output signal from the Gm circuit 237 is negatively fed back to the reverse-phase input terminal thereof. In addition, a node where the output terminals of the Gm circuits 235 to 237 are connected becomes an output of the frequency characteristic adjusting circuit.

In this circuit configuration, the Gm circuits 231 to 233 constitute the adder 201 of FIG. 5. In addition, the node Nvx where the output terminals are commonly connected corresponds to the signal branching module at a rear stage of the adder 201 in FIG. 5.

The Gm circuit 234 and the capacitor C11 constitute the perfect integrator 202 of FIG. 5. In addition, an output signal from the Gm circuit 234 is negatively fed back to the Gm circuit 232 through the node Nvc. By this connection configuration, a negative feedback circuit where a signal is input to the adder 201 from the perfect integrator 202 in FIG. 5 through the inverter 203 is realized.

The Gm circuits 235 to 237 constitute the adder 205 of FIG. 5. In addition, an amplification factor of the amplifier 204 of FIG. 5 is given by a ratio between gm02/gm01 as each transconductance ratio of the Gm circuits 233 and 237, and GmZ/GmP as each transconductance ratio of the Gm circuits 235 and 232.

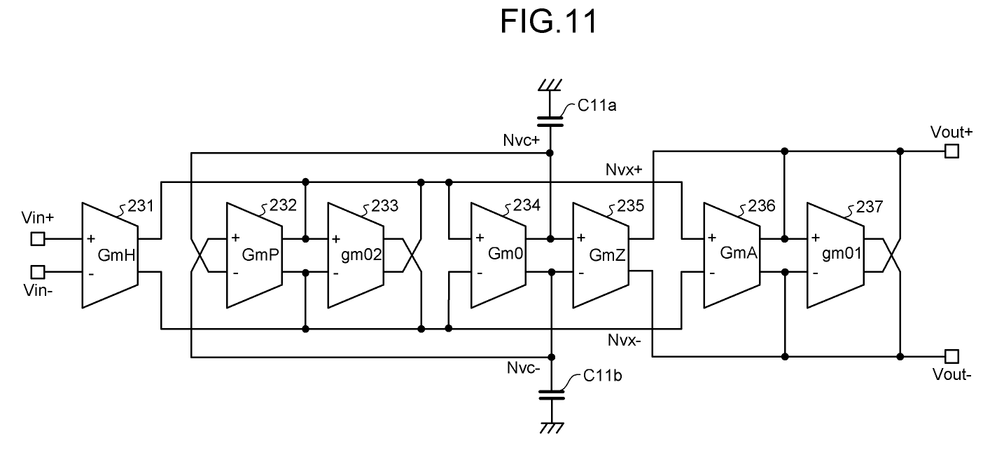

FIG. 11 is a diagram of a configuration where the circuit example 2-1 of the frequency characteristic adjusting circuit is realized in a differential type. In the frequency characteristic adjusting circuit illustrated in FIG. 11, the Gm circuits 231 to 237 correspond to the circuits in FIG. 10 designated by the same reference numerals. Further, capacitors C11a and C11b are obtained by connecting the capacitor C11 of FIG. 10 to both sides of a differential signal line. In the configuration of FIG. 11, a connection relationship between the individual circuits is the same as that of FIG. 10.

That is, the Gm circuits 231 to 233 constitute the adder 201 of FIG. 5. Further, in nodes Nvx+ and Nvx−, the output terminals of the Gm circuits 231 and 232 are connected with the same phase, and the output terminal of the Gm circuit 233 is connected by reverse-phase connection. In addition, the nodes Nvx+ and Nvx− correspond to the signal branching module at the rear stage of the adder 201 in FIG. 5.

The Gm circuit 234 and the capacitors C11a and C11b constitute the perfect integrator 202 of FIG. 5. In addition, the output terminal of the Gm circuit 234 is connected by reverse-phase connection to an input terminal of the Gm circuit 232 through nodes Nvc+ and Nvc−. By this connection configuration, a negative feedback circuit where a signal is input to the adder 201 from the perfect integrator 202 in FIG. 5 through the inverter 203 is realized.

The Gm circuits 235 to 237 constitute the adder 205 of FIG. 5. In addition, an amplification factor of the amplifier 204 of FIG. 5 is given by a ratio between gm02/gm01 as each transconductance ratio of the Gm circuits 233 and 237 and GmZ/GmP as each transconductance ratio of the Gm circuits 235 and 232.

In both the configurations of FIGS. 10 and 11, an input stage circuit of the frequency characteristic adjusting circuit is configured by the Gm circuit. This circuit generally becomes high input impedance, and the input impedance may be considered to be infinite. For this reason, even when each circuit is connected to the rear stage of the AC coupling circuit 100, input impedance of a receiving end when viewed from a transmitting end of the transmission path does not vary.

Next, transfer characteristics in the circuits of FIGS. 10 and 11 will be described. In this case, for the simplification of description, the case of FIG. 10 where the frequency characteristic adjusting circuit is realized in the single end type has been described. However, the same transfer characteristic is realized even in the case of FIG. 11 where the frequency characteristic adjusting circuit is realized in the differential type.

In FIG. 10, Vin is an input signal voltage of the frequency characteristic adjusting circuit, Vout is an output signal voltage thereof, Vx is a voltage of a node Nvx, and Vc is a voltage of a node Nvc. First, focusing on the node Nvx, a relationship as follows is realized by a Kirchhoff's first law (current continuous side):

GmH·Vin+GmP·(−Vc)+gm02·(−Vx)=0 (3)

Further, focusing on an accumulated charge of the capacitor C11, a voltage Vc of the node Nvc is given as follows:

Vc=(Gm0/S·C)·Vx (4)

where C is a capacity of the capacitor C11. From Equations 3 and 4, the voltages Vx and Vc of the nodes Nvx and Nvc are calculated by the following Equations 5 and 6.

$$\begin{matrix}\begin{matrix}Vx = \frac{GmH}{gm 02 + GmP \cdot \frac{Gm}{S \cdot C}} \cdot Vin \\ = \frac{GmH}{gm 02} \cdot \frac{S}{S + ( \frac{GmP}{gm 02} ) \cdot \frac{Gm 0}{C}} \cdot Vin\end{matrix} & ( 5 ) \\ Vc = \frac{GmH}{gm 02} \cdot \frac{\frac{Gm 0}{C}}{S + ( \frac{GmP}{gm 02} ) \cdot \frac{Gm 0}{C}} \cdot Vin & ( 6 )\end{matrix}$$

With respect to an output signal voltage Vout of the frequency characteristic adjusting circuit, a relationship as follows is realized by the Kirchhoff's first law (current continuous side):

GmZ·Vc+GmA·Vx+gm01·(−Vout)=0 (7)

From the above Equations, the transfer function of the frequency characteristic adjusting circuit of FIG. 10 is calculated as follows:

$$\begin{matrix}{T}_{1} ( S ) = \frac{GmH}{gm 02} \cdot \frac{\frac{GmZ}{gm 01} \cdot \frac{Gm 0}{C} + \frac{GmA}{gm 01} \cdot S}{S + ( \frac{GmP}{gm 02} ) \cdot \frac{Gm 0}{C}} \\ = Kh \cdot \frac{Ka \cdot S + Kz \cdot ω 0}{S + Kp \cdot ω 0}\end{matrix} \qquad ( 8 )$$

In this case, the parameters of Equation 8 are given as follows:

ω0=Gm0/C (9)

Kp=GmP/gm02 (10)

Kh=GmH/gm02 (11)

Kz=Gmz/gm01 (12)

Ka=GmA/gm01 (13)

where ω0 is an initial setting value of the moved low-frequency cutoff, and Kp is a coefficient to scale the initial designed frequency ω0 and can be used as one of the parameters to adjust the low-frequency cutoff. In this example, a relationship of Kp·ω0=ωp is realized. The coefficient Kh can be used as a parameter to adjust a gain amount of a high-pass adjusting module in the frequency characteristic of the frequency characteristic adjusting circuit. Similar to the coefficient Kp, Kz is a coefficient to scale the initial designed frequency o0, and in this example, a relationship of Kz·ω0=ωz is realized. The coefficient Ka can be used as a parameter to adjust a gain amount of the high-pass adjusting module in the frequency characteristic of the frequency characteristic adjusting circuit. Since these parameters are independent from each other, an orthogonal adjustment is enabled.

The above Equations are general solutions of the circuit illustrated in FIG. 10, and in the transfer function of the frequency characteristic adjusting circuit 200a illustrated in FIG. 3 or 5, the following relationship is realized. First, from Kh=Ka=1, relationships of GmH=gm02 and GmA=gm01 are realized. Further, with respect to the zero-point frequency ωz and the pole frequency ωp, the following relationships are realized:

ωz=Kz·ω0=(GmZ/gm01)·(Gm0/C) (14)

ωp=Kp·ω0=(GmP/gm02)·(Gm0/C) (15)

Further, a gain of the amplifier 204 illustrated in FIG. 5 is given as follows:

Gain=ωz/ωp=(gm02/gm01)·(GmZ/GmP) (16)

In this case, a function of the amplifier 204 does not appear as a clear hardware block in the circuit configurations of FIGS. 10 and 11. For this reason, after considering the operation of the frequency characteristic adjusting circuit, a gain value of Equation 16 does not need to be particularly considered.

Accordingly, on the basis of the basic relationships like Equations 14 and 15, the movement amount of the low-frequency cutoff, i.e., the pole frequency ωp can be controlled. For example, the movement amount of the low-frequency cutoff can be controlled by varying the transconductances GmP, Gm0, and GmZ of the Gm circuits 232, 234, and 235. As exemplified in the following drawings, in the Gm circuit, a transconductance value can be continuously varied by varying a value of a control current, and the low-frequency cutoff can be simply set to an arbitrary value. In this case, a control current to vary the transconductance corresponds to the control signal illustrated in FIG. 1, and an input terminal of the control signal in the frequency characteristic adjusting circuit corresponds to the control signal inputting module 22 illustrated in FIG. 1.

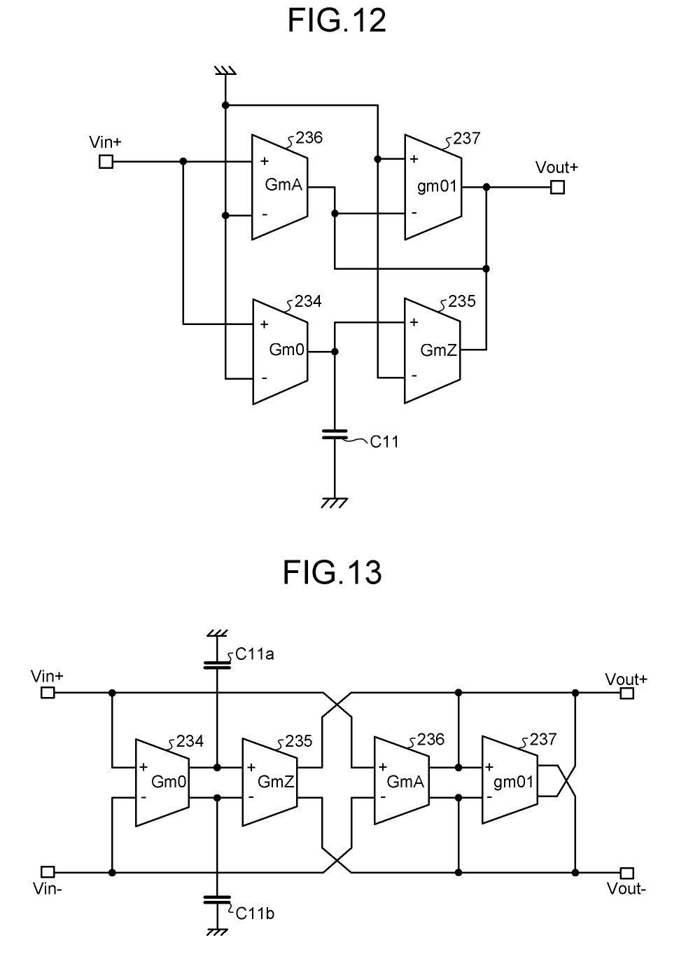

FIG. 12 is a diagram of a configuration where the circuit example 2-2 of the frequency characteristic adjusting circuit is realized in a single end type. In the frequency characteristic adjusting circuit illustrated in FIG. 12, the Gm circuits 234 to 237 and the capacitor C11 correspond to the circuits in FIG. 10 designated by the same reference numerals. The circuit of FIG. 12 is equivalent to the case where the Gm circuit 232 enters in open state, i.e., a non-output state, and GmH=gm02 is set with respect to the transconductance GmH of the Gm circuit 231 of the input stage, in the circuit of FIG. 10. That is, by this setting operation, an input signal of the circuit of FIG. 10 is input to the Gm circuits 234 and 236 as it is.

In the circuit configuration of FIG. 12, the Gm circuit 234 and the capacitor C11 constitute the perfect integrator 211 of FIG. 8. Further, the Gm circuits 235 to 237 constitute the adder 212 of FIG. 8.

FIG. 13 is a diagram of a configuration where the circuit example 2-2 of the frequency characteristic adjusting circuit is realized in a differential type. In the frequency characteristic adjusting circuit illustrated in FIG. 13, the Gm circuits 234 to 237 and the capacitors C11a and C11b correspond to the circuits in FIG. 11 designated by the same reference numerals. The circuit of FIG. 13 is equivalent to the case where the Gm circuit 232 enters an open state, and the transconductance GmH of the Gm circuit 231 of the input stage and the transconductance gm02 of the Gm circuit 233 are equally set, in the circuit of FIG. 11. That is, by this setting operation, an input signal of the circuit of FIG. 11 is input to the Gm circuits 234 and 236 as it is.

In FIGS. 12 and 13, if the Gm circuit 232 enters in open state, this case corresponds to the case where the switch SW3 is turned off in the circuit of FIG. 9. This operation can be realized by setting a value of a bias current input to the Gm circuit 232 to “0”.

In this manner, the transfer function of the circuits of FIGS. 12 and 13 is calculated as follows:

$${T}_{2} ( S ) = \frac{GmA}{gm 01} + \frac{\frac{GmZ}{gm 01} \cdot \frac{Gm 0}{C}}{S} = Ka + \frac{Kz \cdot ω 0}{S} \qquad ( 17 )$$

The operation for turning off a switch SW4 in the circuit of FIG. 9 can be realized by stopping supply of a bias current in at least one of the Gm circuit 234 and the Gm circuit 235.

From a relationship of the individual parameters, between the values of the transconductance and the capacitor C11 or the capacitors C11a and C11b in the circuit example 2-2, and the circuit parameter in the AC coupling circuit 100 at the previous stage, relationships of the following Equations 18 and 19 are set, and thereby control, such as change of the low-frequency cutoff or offset of the low-pass cutoff characteristic, is enabled. Further, Cp indicates a capacity of the coupling capacitor C1 of the AC coupling circuit 100, and Rz indicates a resistance value of the terminating resistor R2. Further, Equation 19 is calculated by transforming Equation 18 as follows:

ωz=(GmZ/gm01)·(Gm0/C)=1/(Cp/Rz) (18)

C/Cp=(GmZ/gm01)·Gm0·Rz (19)

In Equation 19, the capacities C and Cp and the resistance value Rz are fixed values. Accordingly, if the transconductances Gm0 and GmZ of the Gm circuits 234 and 235 are controlled, the low-frequency cutoff can be moved or removed. In particular, as exemplified in the following drawings, in the Gm circuit, the transconductance value can be continuously varied by varying the value of the control current, and the low-frequency cutoff can be simply set to an arbitrary value. In this case, a control current to vary the transconductance corresponds to the control signal illustrated in FIG. 1, and an input terminal of the control signal in the frequency characteristic adjusting circuit corresponds to the control signal inputting module 22 illustrated in FIG. 1.

As an example of the condition that satisfies the relationship of Equation 16, combinations like the following Equations 20 and 21 are considered:

C=Cp (20)

(GmZ/gm01)·Gm0=1/Rz (21)

In this case, when the capacity C of the capacitor C11 or the capacitors C11a and C11b cannot be temporarily set to the capacity Cp of the coupling capacitor C1 or more, a value of the transconductance GmZ or the transconductance Gm0 may be decreased with the same ratio as a capacity ratio. As such, a relative relationship of a circuit parameter in the frequency characteristic adjusting circuit with respect to the circuit parameter of the AC coupling circuit 100 is not particularly important, and a relative relationship of the capacity C and the transconductances Gm0 and GmZ in the frequency characteristic adjusting circuit may be considered.

Next, the detailed circuit configuration of each Gm circuit illustrated in FIGS. 10 to 13 will be exemplified.

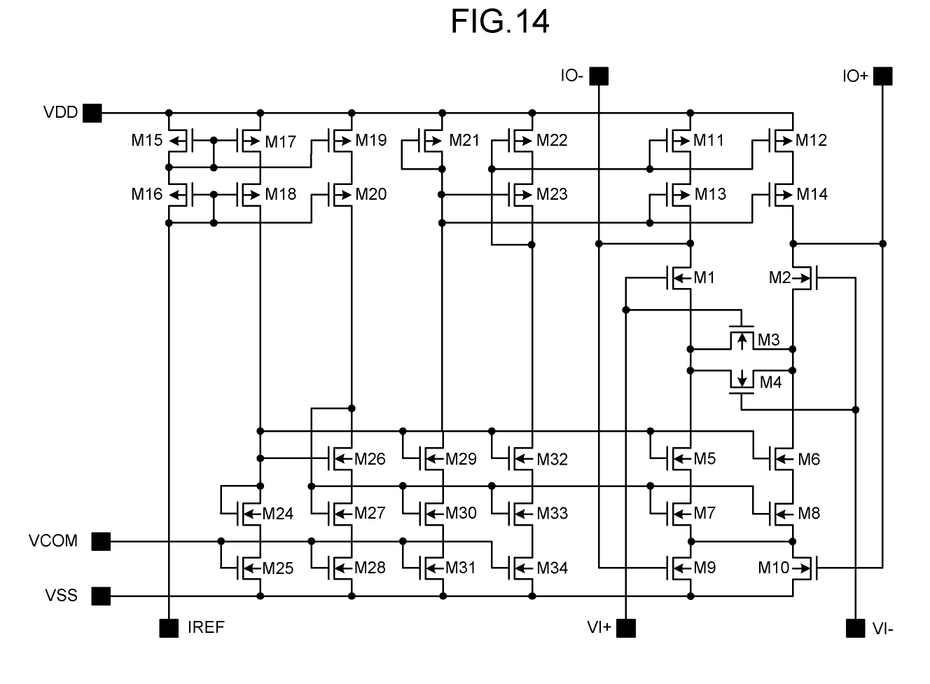

FIG. 14 is an exemplary diagram of the circuit configuration of a Gm circuit.

In the Gm circuit illustrated in FIG. 14, input voltages VI+ and VI− are applied to gates of transistors M1 and M2, respectively, and output currents IO− and IO+ are extracted from drains thereof, respectively. The transistors M1 and M2 constitute a differential voltage/current amplifying stage. Transistors M3 and M4 are inserted between sources of the transistors M1 and M2, and operate as variable resistors according to an input signal in a triode area. Further, as a voltage between a gate and a source in each of the transistors M1 and M2, a voltage between a gate and a source in each of the transistors M3 and M4 is applied. In addition, a bias current IREF applied from the outside is amplified by a current mirror stage to be described in detail below, and the transconductance of the Gm circuit is adjusted by the amplified current.

The transistors M15 and M17 constitute a current mirror. Also, the transistors M15 and M19 constitute a current mirror. In these circuits, the bias current IREF is amplified according to a size ratio of the transistors M15 and M17 and a size ratio of the transistors M15 and M19.

In this case, a drain current of a complementary metal oxide semiconductor (CMOS) transistor in a saturation region is represented as follows:

Id=K·(W/L)·(Vgs−Vth)2 (22)

where K is an integer determined by a physical property of a device, W is a gate width, L is a gate length, W/L is an aspect ratio, Vgs is a voltage between a gate and a source, and Vth is a threshold voltage. The relationships between drain currents, gate widths, and gate lengths of the transistors M15, M17, and M19 are represented as follows:

I17/I15=(W17/L17)/(W15/L15) (23)

I19/I15=(W19/L19)/(W15/L15) (24)

where the drain currents of the transistors M15, M17, and M19 are I15, I17, and I19, the gate widths of the transistors M15, M17, and M19 are W15, W17, and W19, and the gate lengths of the transistors M15, M17, and M19 are L15, L17, and L19. As illustrated in Equations 23 and 24, a current ratio of a current mirror is determined by a gate size ratio of the transistors constituting the current mirror.

Further, the drains of the transistors M15, M17, and M19 are connected to the transistors M16, M18, and M20. The transistors M18 and M20 are provided to equalize drain potentials of the transistors M17 and M19 with a drain potential of the transistor M15. Thereby, current is suppressed from varying due to a difference of voltages between drains and sources in the individual transistors.

Similar to the above case, each combination of the transistors M27 and M30, the transistors M27 and M33, the transistors M27 and M7, and the transistors M27 and M8 constitutes a current mirror. In addition, in a current mirror circuit, a drain current is applied by a gate size ratio of the comprised transistors. Further, the transistors M26, M29, M32, M5, and M6 are provided to equalize drain potentials of the transistors M27, M30, M33, M7, and M8. Thereby, current is suppressed from varying due to a difference of voltages between drains and sources.

Similarly, each combination of the transistors M22 and M11 and the transistors M22 and M12 also constitutes a current mirror. In addition, a drain current is applied by a gate size ratio of the transistors of each combination. Further, the transistors M23, M13, and M14 are provided to equalize drain potentials of the transistors M22, M11, and M12. Thereby, a current is suppressed from varying due to a difference of voltages between the drains and the sources.

Meanwhile, in a current path of the transistors M5 and M7 and the transistors M11 and M13, the configuration of cascade connection is basically adopted. This causes an effect of increasing impedance as an active load, in addition to the effect of suppressing the variation in the current as described above. For example, impedance measured from a drain in the case of cascode connection is schematically represented as follows:

Z0=r0·(gm·r0) (25)

where resistance between a drain and a source for one transistor stage is r0 and transconductance in a saturation region is gm. According to Equation 25, as compared with the case where the cascode connection is not made, impedance is increased to (gm·r0) times as much, and the high impedance is obtained.

As described above, the transistors M1 and M2 constitute a differential voltage/current amplifying stage, and the transistors M3 and M4 as variable resistors are inserted between the sources thereof. When a differential pair is unbalanced, for example, when a gate potential of the transistor M1 is at a high level and a gate potential of the transistor M2 is at a low level, gate and source potentials of the transistor M4 are lowered. For this reason, the transistor M4 enters in an operation state in the saturation region, but the transistor M3 operates in a triode region. As such, regardless of a value of an input signal, either the transistor M3 or the transistor M4 is held in the triode region and operates as the variable resistor.

The sources of the transistors M7 and M8 are connected to the transistors M9 and M10, and the transistors operate in the triode region and form a common mode feedback loop. Further, the sources of the transistors M25, M28, M31, and M34 are commonly connected to the sources of the transistors M9 and M10, and a reference voltage VCOM is input to the gates of the transistors M25, M28, M31, and M34. In this configuration, if current ratios to transistor sizes are the same with respect to all of the transistors M25, M28, M31, M34, M9, and M10, negative feedback is configured such that voltages between gates and sources of the transistors M9 and M10 become equal to voltages between gates and sources of the transistors M25, M28, M31, and M34, i.e., the reference voltage VCOM. In addition, the voltages between the gates and sources of the transistors M9 and M10 are an output operation-point voltage of the Gm circuit.

The transistors M24, M26, and M27 operate as a current post circuit for a current mirror that corresponds to cascode connection of the transistors M5 and M7 as current sources. The transistor M26 is a gate ground transistor for cascode connection, and the transistor M24 provides a bias for a gate ground with respect to the transistor M26. Further, a voltage between the drain and the source of the transistor M27 becomes a difference of overdrive voltages of the transistors M24 and M26, and the transistor M27 operates in the saturation region.

In this case, to equalize a current that flows through each current post circuit, a condition of the following Equation 26 is provided as an aspect ratio of the gate:

(W24/L24)≦(1/4)·(W27/L27) (26)

where W24 and W27 are gate widths of the transistors M24 and M27, respectively, and L24 and L27 are gate lengths of the transistors M24 and M27, respectively. To hold the transistor M27 in the saturation region, the gate width of the transistor M27 may be decreased to ¼ times or less as much, or the gate length may be increased to four times or more as much.

Similar to the above transistors, positive MOS (PMOS) transistors M21, M22, and M23 also operate as a current post circuit for a current mirror that corresponds to the transistors M13 and M14. Accordingly, between the transistors M21, M22, and M23, the same relationship as the relationship between the transistors M24, M26, and M27 is realized. By this configuration, the voltages between the drains and the sources of the transistors at the current mirror stage are decreased to about a boundary of the saturation region, and an effective operation voltage in a body circuit module that varies transconductance is set as large as possible.

As such, in the Gm circuit, if the amount of the bias current IREF as the control current is controlled, the transconductance can be continuously varied. As described above, according to the second embodiment, the transconductances GmP, Gm0, and GmZ are varied by controlling the bias current with respect to the Gm circuits 232, 234, and 235, and the low-frequency cutoff can be moved or removed.

### Third Embodiment

In the second embodiment, the case where the primary filter is applied as the AC coupling circuit has been described. However, even when a secondary filter is applied as the AC coupling circuit, the low-frequency cutoff in the AC coupling circuit can be moved by the frequency characteristic adjusting circuit.

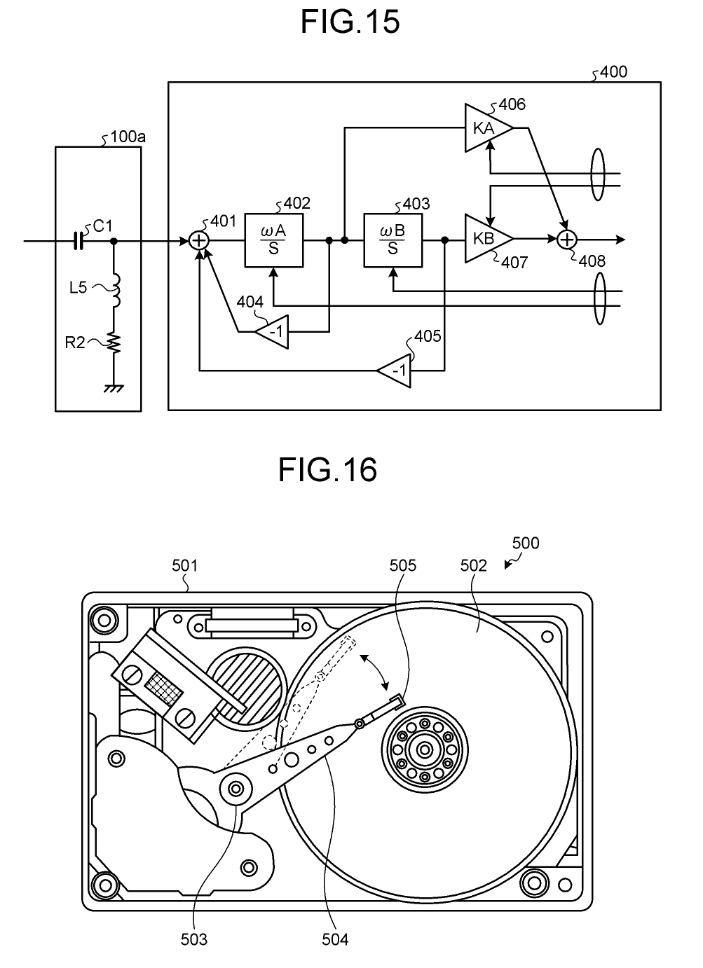

FIG. 15 is a block diagram where a transfer function of a frequency characteristic adjusting circuit according to a third embodiment of the invention is expanded. In FIG. 15, an AC coupling circuit 100a comprises a coupling capacitor C1 that is directly connected to a transmission path, and a coil L5 and a terminating resistor R2 that are connected in series between the transmission path and a ground. This circuit constitutes a secondary high-pass filter. If inductance of the coil L5 is Lz, a transfer function of the AC coupling circuit 100a is represented as follows:

$${T}_{A C} ( S ) = \frac{{S}^{2} + \frac{Rz}{Lz} \cdot S}{{S}^{2} + \frac{Rz}{Lz} \cdot S + \frac{1}{Lz \cdot Cp}} \qquad ( 27 )$$

Meanwhile, a frequency characteristic adjusting circuit 400 that shifts the low-frequency cutoff of the AC coupling circuit 100a comprises an input-side adder 401, two perfect integrators 402 and 403, two inverters 404 and 405, two amplifiers 406 and 407, and an output-side adder 408.

The adder 401 has three input terminals, and one input terminal receives an output signal from the AC coupling circuit 100a. Further, between the other two input terminals, one input terminal receives an inverted signal obtained by inverting an output signal from the perfect integrator 402 by the inverter 404, and the other input terminal receives an inverted signal obtained by inverting an output signal from the perfect integrator 403 by the inverter 405. The adder 401 adds the input signals and outputs an added signal to the perfect integrator 402.

The perfect integrator 402 is a circuit that is represented by a transfer function ωA/S, and has a cutoff frequency ωA. An output signal from the perfect integrator 402 is split into the perfect integrator 403, the inverter 404, and the amplifier 406. The perfect integrator 403 is a circuit that is represented by a transfer function ωB/S, and has a cutoff frequency ωB. An output signal from the perfect integrator 403 is split into the inverter 405 and the amplifier 407. In this case, the cutoff frequencies ωA and ωB correspond to a pole frequency of the frequency characteristic adjusting circuit 400. Accordingly, the perfect integrators 402 and 403 can receive a control signal to vary the pole frequency.

The amplifier 406 has a gain KA and the amplifier 407 has a gain KB. Output signals from the amplifiers 406 and 407 are added by the adder 408 and are output. In this case, the gains KA and KB can be used as parameters to vary a zero-point frequency of the frequency characteristic adjusting circuit 400. Accordingly, the amplifiers 406 and 407 can receive a control signal to vary the zero-point frequency.

A transfer function of the frequency characteristic adjusting circuit 200a is represented as follows:

$${T}_{INF} ( S ) = \frac{{S}^{2} + KA \cdot ω A \cdot S + KB \cdot ω A \cdot ω B}{{S}^{2} + ω A \cdot S + ω A \cdot ω B} \qquad ( 28 )$$

As described above, to offset the low-pass cutoff characteristic of the AC coupling circuit 100a, a numerator polynomial of a transfer function of the frequency characteristic adjusting circuit 200a may match a denominator polynomial of a transfer function of the AC coupling circuit 100a. Accordingly, between the transfer functions of the individual circuits illustrated in Equations 27 and 28, the following relationships may be realized:

KA·ωA=Rz/Lz (29)

KB·ωA·ωB=1/(Lz·Cp) (30)

From Equations 29 and 30, between the individual circuit parameters of the AC coupling circuit 100a and the frequency characteristic adjusting circuit 200a, the following relationship may be realized:

(KB/KA)·ωB=1/(Cp·Rz) (31)

When the relationship of Equation 31 is satisfied, the transfer functions of the AC coupling circuit 100a and the frequency characteristic adjusting circuit 200a are represented as follows:

$$\begin{matrix}{T}_{0} ( S ) = {T}_{A C} ( S ) \cdot {T}_{INF} ( S ) \\ = \frac{{S}^{2} + \frac{Rz}{Lz} \cdot S}{{S}^{2} + ω A \cdot S + ω A \cdot ω B} \end{matrix} \qquad ( 32 )$$

In this case, since the capacity Cp, the resistance value Rz, and inductance Lz are already known, the cutoff frequency ωB of the integrator 403 and the individual gains KA and KB of the amplifiers 406 and 407 may be varied such that the relationship of Equation 31 is realized. At this time, the cutoff frequency ωB is used when a new low-frequency cutoff is adjusted by the AC coupling circuit 100a and the frequency characteristic adjusting circuit 200a. For this reason, the gain KA needs to be adjusted together with the cutoff frequency ωB.

Accordingly, a ratio between the cutoff frequency ωB and the gain KA is maintained at an arbitrary constant value and the gain KB is controlled, and a right side of Equation 31 matches 1/(Cp·Rz) of a left side. As a result, the zero-point frequency of the frequency characteristic adjusting circuit 200a matches the low-frequency cutoff of the AC coupling circuit 100a. After the gain KB is determined in the manner as described above, a control signal with respect to the perfect integrator 403 and the amplifier 406 is varied in a state where the ratio between the cutoff frequency ωB and the gain KA is constantly maintained. As a result, the pole frequency of the frequency characteristic adjusting circuit 200a is varied, and a new low-frequency cutoff of the AC coupling circuit 100a and the frequency characteristic adjusting circuit 200a is adjusted.

### Fourth Embodiment

In a fourth embodiment of the invention, the case where the frequency characteristic adjusting circuit is applied to an HDD will be described.

FIG. 16 is a plan view of an inner configuration of an HDD 500 according to the fourth embodiment. In the HDD 500 illustrated in FIG. 16, in a disk enclosure 501, a magnetic disk 502 as a recording medium, and a carriage arm 504 that can be rotated by an actuator (not illustrated) about a rotation shaft 503 are stored. In addition, a magnetic head 505 mounted in a front end of the carriage arm 504 scans the magnetic disk 502 from the upper side, information is written in the magnetic disk 502, and the information is read out from the magnetic disk 502.

Further, on a back surface of the disk enclosure 501, a main board (not illustrated) is disposed. On the main board, a circuit that modulates a recording signal of the magnetic disk 502 or demodulates the read signal or a control circuit to control the rotation of the magnetic disk 502 or the carriage arm 504 is mounted. In addition, the main board and the magnetic head 505 in the disk enclosure 501 are connected by a flexible board (not illustrated), and the recording signal or the reproduction signal is transmitted through the flexible board. Further, a connector or a relay board may be provided between the magnetic head 505 and the main board.

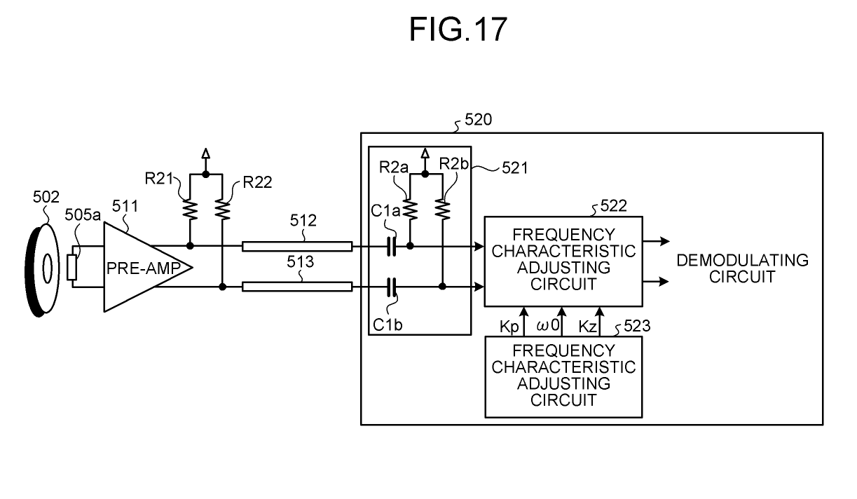

FIG. 17 is a diagram of a circuit configuration of a reproduction signal system in the HDD. A reproduction head 505a that reads a signal from the magnetic disk 502 is connected to a read channel 520 through a preamplifier 511 and transmission paths 512 and 513. The preamplifier 511 is mounted near the rotation shaft 503 of the carriage arm 504 in the disk enclosure 501 or on the carriage arm 504. Meanwhile, the read channel 520 comprises a demodulating circuit of a reproduction signal received through the transmission paths 512 and 513, which is a circuit provided on the main board. Accordingly, each of the transmission paths 512 and 513 corresponds to a flexible board coupling the preamplifier 511 and the main board, a wring line up to the read channel 520 on the main board, a connector disposed between the preamplifier 511 and the main board, or a relay board.

Transmitting ends of the transmission paths 512 and 513 are terminated by the resistors R21 and R22. Meanwhile, receiving ends of the transmission paths 512 and 513 are connected to an AC coupling circuit 521 mounted in the read channel 520. The AC coupling circuit 521 corresponds to the AC coupling circuit 100 in the second embodiment, and comprises a primary high-pass filter that is configured by the coupling capacitors C1a and C1b and the terminating resistors R2a and R2b. In addition, the receiving ends of the transmission paths 512 and 513 are AC coupled by the coupling capacitors C1a and C1b, and matching terminated by the terminating resistors R2a and R2b.

Further, in the read channel 520, a frequency characteristic adjusting circuit 522 is connected to a rear stage of the AC coupling circuit 521. The frequency characteristic adjusting circuit 522 receives a control signal to adjust a frequency characteristic, from a Gm control circuit 533 mounted in the read channel 520. Further, the Gm control circuit 533 may be provided outside the read channel 520.

If the configuration of the circuit example 2-1 is applied as the frequency characteristic adjusting circuit 522, signals to control coefficients Kp and Kz and an initial designed frequency ω0 may be input from the Gm control circuit 533. As described above, these parameters can be continuously controlled according to the bias current supplied to the corresponding Gm circuit in the frequency characteristic adjusting circuits 522.

In this case, in the HDD, in a transmission path that ranges from an output of a preamplifier of a reproduction signal system to a read channel, AC coupling is generally made, as illustrated in the example of FIG. 17. This is to separate a direct current operation point in the inputting module of the read channel from the output module of the preamplifier and independently design the direct current operation point.

When this configuration is applied, in a reproduction signal, particularly, a reproduction signal from a magnetic disk of a vertical recording method, a direct current component may be generally contained. Accordingly, it is preferable to set the low-frequency cutoff of the AC coupling module as low as possible. However, with respect to a noise containing a large amount of low-pass components, for example, a noise generated due to a thermal asperity (hereinafter, simply “TA”) phenomenon, it is needed to increase the low-frequency cutoff to remove a low frequency noise.

In this case, the TA phenomenon is a phenomenon where a spike-like noise is generated, when a magnetoresistive-effect-type (MR-type) head collides with a protrusion on the magnetic disk. This noise is generated when a resistance value of an MR head element is temporarily varied due to heat generated by collision, and causes an erroneous detection of a reproduction signal.

Meanwhile, as illustrated in FIG. 17, when the frequency characteristic adjusting circuit 522 is provided, the low-frequency cutoff is set to be low, when generation of the TA phenomenon is detected, the low-frequency cutoff is set to be temporarily high, and the generated noise is removed.

In addition, in the HDD, kinds or speeds of transmitted signals may be different at the time of reproducing a signal or servo, or a transmission speed of the read signal at the inner circumferential side and the outer circumferential side of the magnetic disk may be varied, as in a zone-bit recording method. The zone-bit recording method is a recording method in which a radius direction is divided into a plurality of areas and the number of sectors in the outside area is increased, to make a recording density of the entire magnetic disk uniform. For this reason, a transmission speed of a reproduction signal from the outer circumferential side is faster than that from the inner circumferential side.

In this case, the low-frequency cutoff is preferably switched into an optimal value according to a speed of the transmitted signal. As illustrated in FIG. 17, when the frequency characteristic adjusting circuit 522 is provided, adaptive control can be easily performed. For example, a frequency characteristic adjusting circuit 523 of FIG. 17 varies the pole frequency of the frequency characteristic adjusting circuit 522 in accordance with an input signal that can determine whether either the signal reproduction or the servo is executed or an input signal indicating a read address on the magnetic disk 502.

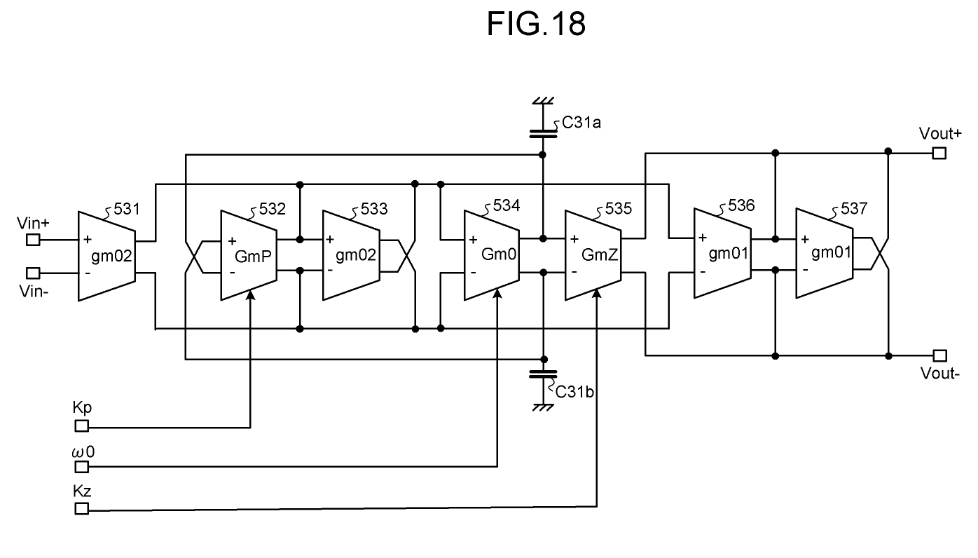

FIG. 18 is a diagram of a configuration of the circuit example 4-1 of the frequency characteristic adjusting circuit. The circuit configuration illustrated in FIG. 18 is basically the same as that of the circuit example 2-1 illustrated in FIG. 11. That is, Gm circuits 531 to 537 and capacitors C31a and C31b in FIG. 18 correspond to the Gm circuits 231 to 237 and the capacitors C11a and C11b in FIG. 11.

However, in the circuit example 4-1 of FIG. 18, for the simplification of description, transconductances of the Gm circuits 531 and 536 are set to the same values as transconductances gm02 and gm01 of the Gm circuits 533 and 537. Thereby, a parameter that does not depend on a frequency is excluded.

Hereinafter, a method of adjusting a frequency characteristic in the circuit example 4-1 will be described. A transfer function in the circuit example 4-1 is represented as follows:

$${T}_{INV 1} ( S ) = \frac{S + ( \frac{GmZ}{gm 01} ) \cdot \frac{Gm 0}{C}}{S + ( \frac{GmP}{gm 02} ) \cdot \frac{Gm 0}{C}} = \frac{S + Kz \cdot ω 0}{S + Kp \cdot ω 0} \qquad ( 33 )$$

In this case, each transconductance gm02 of the Gm circuits 531 and 533 and each transconductance gm01 of the Gm circuits 536 and 537 may be handled as a constant value. Further, each capacity C of the capacitors C31a and C31b is fixed. Meanwhile, the transconductance Gm0 of the Gm circuit 534 is connected to setting of both a zero-point frequency ωz and a pole frequency ωp, as illustrated in Equations 14 and 15.

Accordingly, first, in consideration of the low-frequency cutoff as the fixed value of the AC coupling circuit 521 at the previous stage, and a desired range where the low-frequency cutoff is varied by the frequency characteristic adjusting circuit 522, i.e., a variable range of the pole frequency ωp, a value of the transconductance Gm0 is determined as an initial setting value. Here, since the zero-point frequency ωz is also already known, if the low-frequency cutoff of the AC coupling circuit 521 and an initial setting value of the transconductance Gm0 are determined, transconductance GmZ of the Gm circuit 535 that is a control parameter (see Equation 14) of the zero-point frequency ωz is also determined. Accordingly, the low-frequency cutoff, i.e., the pole frequency ωp can be set as an arbitrary value by the transconductance GmP of the Gm circuit 532 as a control parameter (see Equation 15) of the pole frequency ωp.

In the method of adjusting a frequency characteristic, a variable range of the low-frequency cutoff can be set to be higher than the low-frequency cutoff of the AC coupling circuit 521. In this case, an initial designed frequency ω0 (=Gm0/C) may be set as a value larger than a value of 1/(Cp·Rz), and a condition of GmZ<gm01 as the transconductance may be applied, and the coefficient Kz may be used as an attenuation parameter that is less than “1”. That is, the coefficient Kz is set such that a value of the zero-point frequency (Kz·ω0) based on Equation 14 becomes 1/(Cp·Rz) as the low-frequency cutoff of the AC coupling circuit. Thereby, as a variable range of the low-frequency cutoff, covering is enabled from the high-pass side of the low-frequency cutoff of the AC coupling circuit 521 to the low-pass side.

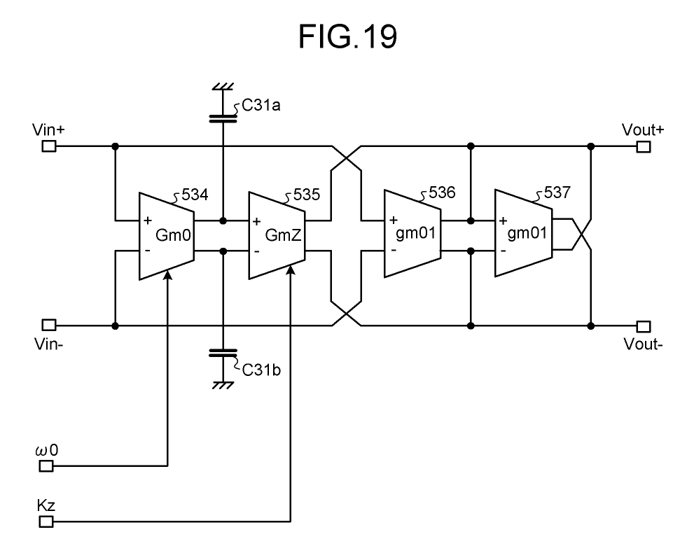

FIG. 19 is a diagram of a configuration of the circuit example 4-2 of the frequency characteristic adjusting circuit. The circuit configuration illustrated in FIG. 19 is basically the same as that of the circuit example 2-2 illustrated in FIG. 12. That is, Gm circuits 534 to 537 and capacitors C31a and C31b in FIG. 19 correspond to the Gm circuits 234 to 237 and the capacitors C11a and C11b in FIG. 12. However, similar to the case of the circuit example 4-1, in the circuit example 4-2 of FIG. 19, transconductance of the Gm circuit 536 is set to the same value as transconductance gm01 of the Gm circuit 537, and a parameter that does not depend on a frequency is excluded.

A transfer function in the circuit example 4-2 is represented as follows:

$${T}_{INV 2} ( S ) = 1 + \frac{\frac{GmZ}{gm 01} \cdot \frac{Gm 0}{C}}{S} = 1 + \frac{Kz \cdot ω 0}{S} \qquad ( 34 )$$

In this case, similar to the case of the circuit example 4-1, each transconductance gm01 of the Gm circuits 536 and 537 may be handled as a constant value, and each capacity C of the capacitors C31a and C31b is fixed. On the basis of Equations 18 and 19 or Equations 20 and 21, the transconductance Gm0 of the Gm circuit 534 and the transconductance GmZ of the Gm circuit 535 are adjusted, thereby matching the zero-point frequency ωz with the low-frequency cutoff of the AC coupling circuit. Thereby, the low-frequency cutoff by the AC coupling circuit 521 is theoretically offset, and an effect of suppressing generation of sag is also obtained.

Next, a modification of the read channel 520 using the frequency characteristic adjusting circuit 522 will be described. In this case, the read channel 520 is provided with a function of detecting a noise due to the TA phenomenon and automatically suppressing the noise.

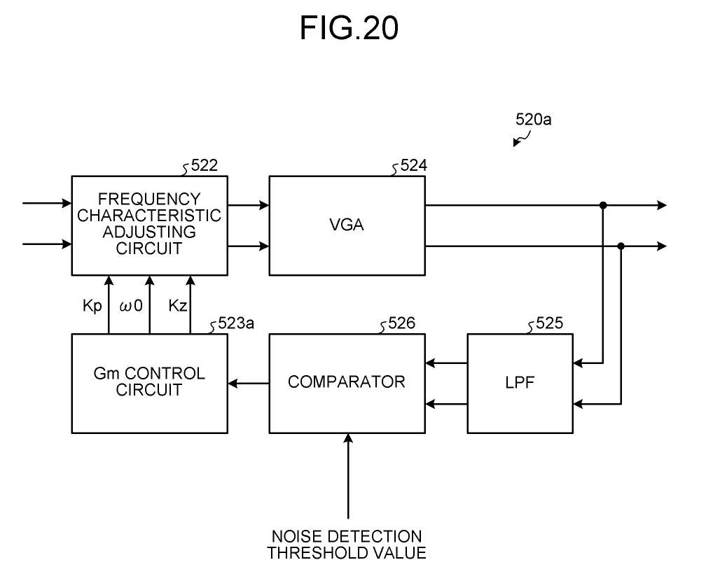

FIG. 20 is a diagram of a configuration of a read channel 520a having a noise suppressing function. The read channel 520a comprises a Gm control circuit 523a, a variable gain amplifier (VGA) 524, a low-pass filter (LPF) 525, and a comparator 526, in addition to the frequency characteristic adjusting circuit 522.

An output signal from the frequency characteristic adjusting circuit 522 is input to the VGA 524. A signal amplified by the VGA 524 is output to a rear stage circuit (not illustrated), such as a signal demodulating circuit, and is split into the LPF 525. The VGA 524 is provided to amplify a signal transmitted to the rear stage circuit, such as the signal modulating circuit or maintain a level of the division signal to the LPF 525 at a predetermined level or more, but this is not essential.

The LPF 525 blocks a high frequency component of an input signal, i.e., a signal component, and detects a low frequency component. Thereby, a noise due to the TA phenomenon is detected. The comparator 526 compares a signal level from the LPF 525 with a predetermined noise detection threshold value, and outputs a flag according to a comparison result. In this case, when the signal level from the LPF 525 is higher than the noise detection threshold value, the flag is given as “1”.

The Gm control circuit 523a outputs a control signal to control a frequency characteristic of the frequency characteristic adjusting circuit 522, similar to the Gm control circuit 523 illustrated in FIG. 17. In this case, as the control signal, a control current with respect to the Gm circuits 532, 534, and 535 is output to vary the initial designed frequency o0 and the coefficients Kp and Kz, as in the above example. The Gm control circuit 523a sets a control current with respect to the frequency characteristic adjusting circuit 522 to a different value in accordance with a value of a flag from the comparator 526, and varies the frequency characteristic.

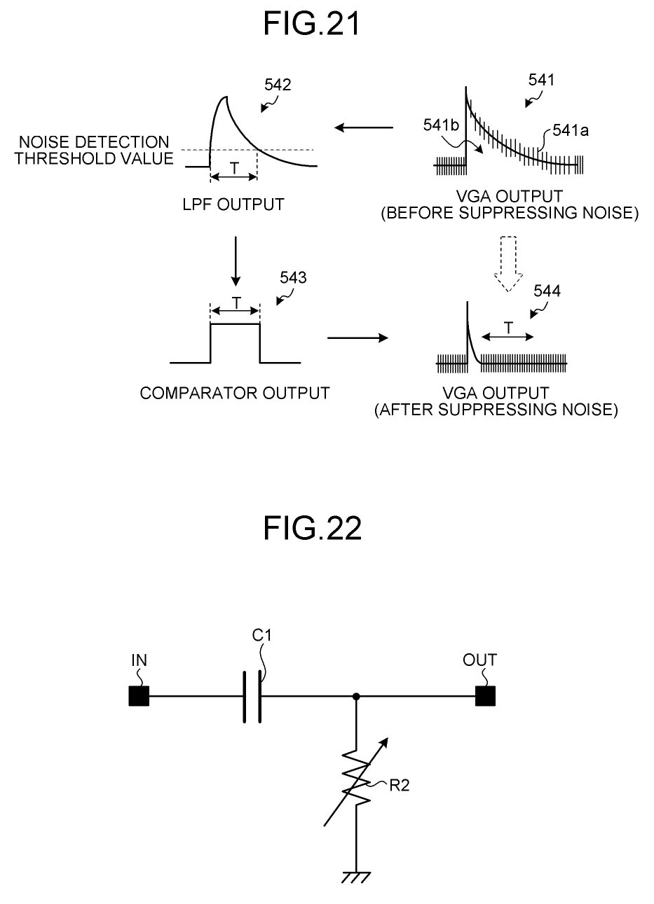

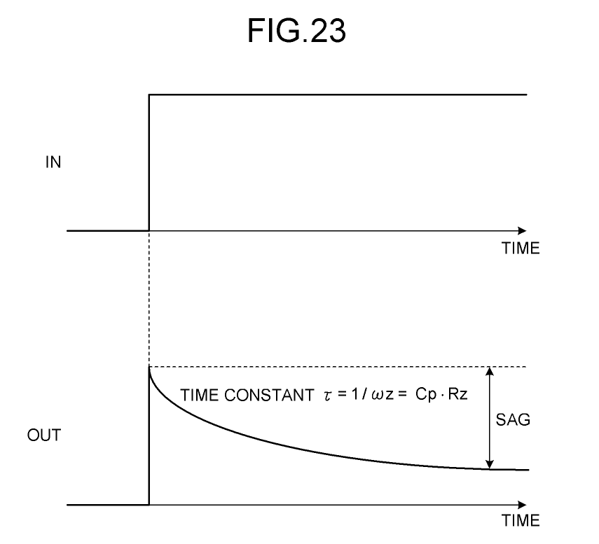

FIG. 21 is a diagram of a signal waveform in each module of the read channel of FIG. 20. A noise suppressing operation in the read channel 520a will be specifically described using FIG. 21.

In a normal state where the flag from the comparator 526 becomes “0”, the pole frequency ωp of the frequency characteristic adjusting circuit 522 is set as a relatively low value by the Gm control circuit 523a, for the purpose of removing a direct current component contained in a received signal. The pole frequency ωp may become “0”. In this state, a waveform 541 of FIG. 21 indicates an output waveform from the VGA 524 in the case where a noise is generated due to the TA phenomenon. The waveform 541 comprises a signal component 541a and a noise component 541b. That is, the noise generated due to the TA phenomenon appears as a spike-like waveform that comprises a large amount of low frequency components, as illustrated in the noise component 541b. For this reason, the noise passes through the AC coupling circuit 521 and the frequency characteristic adjusting circuit 522 without lowering the level thereof.

Accordingly, the noise component 541b is detected by the LPF 525 where the high-frequency cutoff is set to be higher than the pole frequency ωp of the frequency characteristic adjusting circuit 522 in the normal state. A waveform 542 of FIG. 21 indicates an output waveform from the LPF 525, and a signal component is removed and only a noise component is passed.

The comparator 526 varies the flag from “0” to “1” only during a period where a level of the output signal from the LPF 525 exceeds a noise detection threshold value. A waveform 543 of FIG. 21 indicates a transition of a flag from the comparator 526, and an output value becomes “1” only during a period T. That is, during the period T, the noise due to the TA phenomenon is detected.

The Gm control circuit 523a varies a control current to increase the pole frequency ωp of the frequency characteristic adjusting circuit 522 only during a period where the flag from the comparator 526 is “1”. At this time, the pole frequency ωp becomes higher than a high-frequency cutoff in the LPF 525. As the operation of the Gm control circuit 523a during a period where the flag is “1”, for example, the control current may be varied to increase a value of the coefficient Kp as the control parameter of the pole frequency ωp, i.e., a value of the transconductance GmP of the Gm circuit 532 of FIG. 18, in a state where the control parameter of the initial designed frequency ω0 and the coefficient Kz as the control parameter of the zero-point frequency ωz are fixed.

A waveform 544 of FIG. 21 indicates an output waveform from the frequency characteristic adjusting circuit 522 in the case where the pole frequency ωp varies according to the value of the flag, and the noise component is removed during the period T. By this operation, a generation period of the noise due to the TA phenomenon is shortened. For example, in the signal demodulating circuit at the rear stage of the VGA 524, the probability of the erroneous signal detection being generated can be reduced.

In the HDD according to the fourth embodiment, the primary filter is used as the AC coupling circuit, but the secondary filter may be used. For example, when a C-R-L secondary high-pass filter is used, the frequency characteristic adjusting circuit described in the third embodiment can be applied.

As described above, according to an embodiment of the invention, a low cutoff range by an alternate current coupling circuit can be varied according to a control signal, while matching with a transmission path is maintained.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A frequency characteristic adjusting circuit that adjusts a frequency characteristic of an input signal, the frequency characteristic adjusting circuit comprising:
a cutoff range adjusting module configured to be connected to an alternate current coupling circuit capacitively coupled with a signal transmission path and matching terminated, and allow an output signal from the alternate current coupling circuit to pass through such that a low cutoff range in a frequency characteristic of the alternate current coupling circuit varies; and
a control signal inputting module configured to receive a control signal to control a zero-point frequency based on a numerator polynomial of a transfer function of the cutoff range adjusting module and a pole frequency based on a denominator polynomial of the transfer function, wherein
the numerator polynomial of the transfer function of the cutoff range adjusting module is equalized to a denominator polynomial of a transfer function of the alternate current coupling circuit by the control signal, and a cutoff frequency of the low cutoff range is determined by the pole frequency according to the control signal.

2. The frequency characteristic adjusting circuit according to claim 1, wherein, when the alternate current coupling circuit is a primary high-pass filter including a coupling capacitor and a terminating resistor, the transfer function of the cutoff range adjusting module is a bilinear transfer function, the zero-point frequency represented by a root of the numerator polynomial of the transfer function is set to a value equal to a low-frequency cutoff of the alternate current coupling circuit, and the pole frequency represented by a root of the denominator polynomial of the transfer function is a low-frequency cutoff of the low cutoff range.

3. The frequency characteristic adjusting circuit according to claim 2, wherein the cutoff range adjusting module comprises
an integrator configured to have the pole frequency as a cutoff frequency,
a first adder configured to add an inverted signal obtained by inverting an output signal from the integrator and an output signal from the alternate current coupling circuit,
a signal splitter configured to split an output signal from the first adder into a first signal and a second signal, and output the first signal to the integrator,
an amplifier configured to amplify the output signal from the integrator with an amplification factor obtained by dividing the zero-point frequency by the pole frequency, and
a second adder configured to add an output signal from the amplifier and the second signal obtained by the signal splitter.

4. The frequency characteristic adjusting circuit according to claim 3, wherein the cutoff range adjusting module comprises
a first voltage-current converter configured to be connected to an output of the alternate current coupling circuit at an input by normal-phase connection,
a second voltage-current converter,
a third voltage-current converter configured to be connected to outputs of the first voltage-current converter and the second voltage-current converter at an input by reverse-phase connection, and an output is negatively fed back,
a fourth voltage-current converter configured to be connected to the outputs of the first voltage-current converter and the second voltage-current converter at an input by normal-phase connection, and an output is connected to an input of the second voltage-current converter by reverse-phase connection,
a capacitor configured to be connected between the output of the fourth voltage-current converter and a ground potential,
a fifth voltage-current converter configured to be connected to the output of the fourth voltage-current converter at an input by normal-phase connection,
a sixth voltage-current converter configured to be connected to outputs of the first voltage-current converter, the second voltage-current converter, and the third voltage-current converter at an input by normal-phase connection, and
a seventh voltage-current converter configured to be connected to outputs of the fifth voltage-current converter and the sixth voltage-current converter at an input by reverse-phase connection, and an output is negatively fed back, and
the first voltage-current converter, the second voltage-current converter, and the third voltage-current converter are configured to operate as the first adder,
the fourth voltage-current converter and the capacitor are configured to operate as the integrator,
the fifth voltage-current converter, the sixth voltage-current converter, and the seventh voltage-current converter are configured to operate as the second adder, and
the amplification factor of the amplifier is obtained based on a ratio in which numerator is a transconductance ratio of the third voltage-current converter with respect to the seventh voltage-current converter and denominator is a transconductance ratio of the fifth voltage-current converter with respect to the second voltage-current converter.

5. The frequency characteristic adjusting circuit according to claim 4, wherein the zero-point frequency and the pole frequency are controlled by a value of a bias current with respect to each voltage-current converter.

6. The frequency characteristic adjusting circuit according to claim 5, wherein a bias current input to the fourth voltage-current converter and the fifth voltage-current converter is set to be a constant value such that the zero-point frequency matches the low-frequency cutoff of the alternate current coupling circuit and a variable range of the pole frequency is a predetermined value, and the pole frequency is controlled by a value of a bias current to the second voltage-current converter.

7. The frequency characteristic adjusting circuit according to claim 5, wherein a bias current is input to the first voltage-current converter and the third voltage-current converter such that transconductances of the first voltage-current converter and the third voltage-current converter are equalized, and a value of a bias current to the second voltage-current converter is zero, whereby the pole frequency is set to zero.

8. The frequency characteristic adjusting circuit according to claim 3, wherein the cutoff range adjusting module further comprises a switch configured to selectively output the inverted signal obtained by inverting the output signal from the integrator to the first adder.

9. The frequency characteristic adjusting circuit according to claim 2, wherein, when the transfer function of the cutoff range adjusting module is set such that the pole frequency is zero, the cutoff range adjusting module comprises
an integrator configured to receive the output signal from the alternate current coupling circuit and have the zero-point frequency as a cutoff frequency, and
an adder configured to add an output signal from the integrator and the output signal from the alternate current coupling circuit.

10. The frequency characteristic adjusting circuit according to claim 9, wherein the cutoff range adjusting module comprises
a first voltage-current converter configured to be connected to an output of the alternate current coupling circuit at an input by normal-phase connection,
a capacitor configured to be connected between an output of the first voltage-current converter and a ground potential,
a second voltage-current converter configured to be connected to an output of the first voltage-current converter at an input by normal-phase connection,
a third voltage-current converter configured to be connected to the output of the alternate current coupling circuit at an input by normal-phase connection, and
a fourth voltage-current converter configured to be connected to outputs of the second voltage-current converter and the third voltage-current converter at an input by reverse-phase connection, and an output is negatively fed back, wherein
the first voltage-current converter and the capacitor are configured to operate as the integrator, and
the second voltage-current converter, the third voltage-current converter, and the fourth voltage-current converter voltage-current converter are configured to operate as the adder.

11. A receiving interface circuit that receives a signal through a signal transmission path, the receiving interface circuit comprising:
an alternate current coupling circuit configured to be capacitively coupled with the signal transmission path and matching terminated; and
a frequency characteristic adjusting circuit configured to receive an output signal from the alternate current coupling circuit and adjust a frequency characteristic of the alternate current coupling circuit, wherein
the frequency characteristic adjusting circuit comprises
a cutoff range adjusting module configured to allow the output signal from the alternate current coupling circuit to pass through such that a low cutoff range in the frequency characteristic of the alternate current coupling circuit varies, and
a control signal inputting module configured to receive a control signal to control a zero-point frequency based on a numerator polynomial of a transfer function of the cutoff range adjusting module and a pole frequency based on a denominator polynomial of the transfer function, and
the numerator polynomial of the transfer function of the cutoff range adjusting module is equalized to a denominator polynomial of a transfer function of the alternate current coupling circuit by the control signal, and a cutoff frequency of the low cutoff range is determined by the pole frequency according to the control signal.

12. A magnetic storage device that records and reproduces a signal using a magnetic disk medium, the magnetic storage device comprising:
an alternate current coupling circuit configured to be capacitively coupled with a signal transmission path, where a signal read from the magnetic disk medium is transmitted, and matching terminated; and
a frequency characteristic adjusting circuit configured to receive an output signal from the alternate current coupling circuit and adjust a frequency characteristic of the alternate current coupling circuit, wherein
the frequency characteristic adjusting circuit comprises
a cutoff range adjusting module configured to allow the output signal from the alternate current coupling circuit to pass through such that a low cutoff range in the frequency characteristic of the alternate current coupling circuit varies, and
a control signal inputting module configured to receive a control signal to control a zero-point frequency based on a numerator polynomial of a transfer function of the cutoff range adjusting module and a pole frequency based on a denominator polynomial of the transfer function, and
the numerator polynomial of the transfer function of the cutoff range adjusting module is equalized to a denominator polynomial of a transfer function of the alternate current coupling circuit by the control signal, and a cutoff frequency of the low cutoff range is determined by the pole frequency according to the control signal.

13. The magnetic storage device according to claim 12 further comprising:
a low-pass filter configured to receive the output signal from the cutoff range adjusting module and cut off a signal component at a frequency equal to or higher than a predetermined high cutoff frequency; and
a frequency characteristic control module configured to output the control signal such that a cutoff frequency of the low cutoff range of the cutoff range adjusting module is a first frequency lower than the high cutoff frequency in normal state, and output the control signal such that the cutoff frequency of the low cutoff range of the cutoff range adjusting module is a second frequency higher than the high cutoff frequency when level of an output signal from the low-pass filter exceeds a predetermined threshold.
